(19) United States
(12) Patent Application Publication
(10) Pub. No.: US 2025/0167146 A1
(43) Pub. Date: May 22, 2025

(54) MULTI-TIER SEMICONDUCTOR DIE STACKS USING METAL-TO-METAL BONDING AND METHODS OF FORMING THE SAME

(71) Applicant: Taiwan Semiconductor Manufacturing Company Limited, Hsinchu (TW)

(72) Inventors: Sheng-An Kuo, Hsinchu (TW); Chen-Sheng Lin, Taoyuan City (TW); Chao-Wen Shih, Zhubei City (TW); Kuo-Chiang Ting, Hsinchu City (TW); Yen-Ming Chen, Chu-Pei City (TW)

(21) Appl. No.: 18/515,320

(22) Filed: Nov. 21, 2023

(51) Int. Cl. H01L 23/00; H01L 23/498; H01L 25/065

(52) U.S. Cl. CPC H01L 24/05; H01L 23/49816; H01L 23/49822; H01L 24/97; H01L 25/0655; H01L 2224/05025; H01L 2224/05073; H01L 2224/97; H01L 2924/014; H01L 2924/10253; H01L 2924/1431

(57) ABSTRACT

A first wafer having a two-dimensional array of first semiconductor dies including arrays of first top metal bonding pads attached to a top surface of a first carrier wafer. A second wafer having a two-dimensional array of second semiconductor dies including arrays of second top metal bonding pads and arrays of second bottom metal bonding pads bonded to the first wafer by performing a first metal-to-metal bonding process in which the arrays of first top metal bonding pads are bonded to the arrays of second bottom metal bonding pads through first intermetallic diffusion. A third wafer having a two-dimensional array of third semiconductor dies including arrays of third bottom metal bonding pads bonded to the second wafer by performing a second metal-to-metal bonding process in which the arrays of second top metal bonding pads are bonded to the arrays of third bottom metal bonding pads through second intermetallic diffusion.

### BACKGROUND

Multiple semiconductor chips may be vertically stacked to provide a semiconductor package with a reduced package area, an increased data transfer rate, and enhanced performance.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic diagram illustrating a sequence of processing steps that may be used to form composite packages according to an aspect of the present disclosure.

FIG. 2 is a vertical cross-sectional view of a silicon-based wafer that may be used during fabrication of the composite packages of the present disclosure.

FIGS. 3A-3C are sequential vertical cross-sectional views of a first exemplary structure during formation of a first reconstituted wafer that may be used during fabrication of the composite packages of the present disclosure.

FIGS. 4A-4C are sequential vertical cross-sectional views of a second exemplary structure during formation of a second reconstituted wafer that may be used during fabrication of the composite packages of the present disclosure.

FIGS. 5A-5L are vertical cross-sectional view of various configurations of a first composite package according to embodiments of the present disclosure.

FIGS. 6A-6L are vertical cross-sectional view of various configurations of a second composite package according to embodiments of the present disclosure.

FIGS. 7A-7D are vertical cross-sectional view of various configurations of a third composite package according to embodiments of the present disclosure.

FIGS. 8A-8D are vertical cross-sectional view of various configurations of a fourth composite package according to embodiments of the present disclosure.

FIG. 9 is a first flowchart illustrating steps for forming a semiconductor structure according to an embodiment of the present disclosure.

FIG. 10 is a second flowchart illustrating steps for forming a semiconductor structure according to an embodiment of the present disclosure.

FIG. 11 is a third flowchart illustrating steps for forming a semiconductor structure according to an embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

The present disclosure is directed to semiconductor structures, and particularly to a method of forming composite packages including a vertical stack of three or more semiconductor dies that may be stacked along a vertical direction using metal-to-metal bonding thereamongst and methods of forming the same. The various aspect of the present disclosure are now described with reference to accompanying drawings.

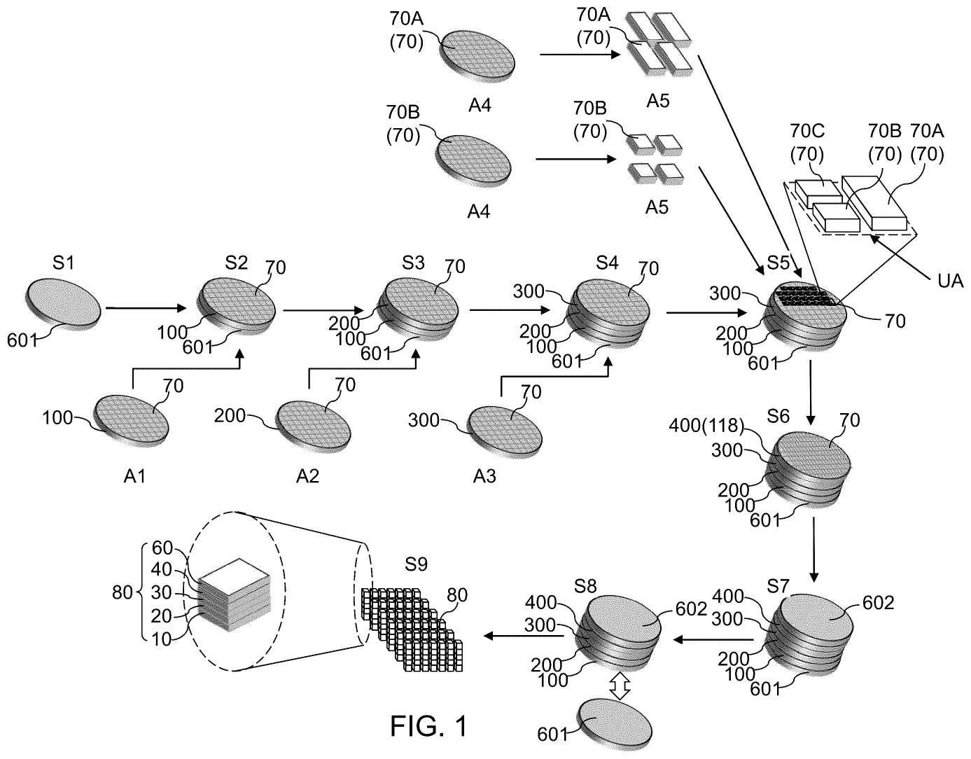

Referring to FIG. 1, a sequence of processing steps that may be used to form composite packages 80 according to an aspect of the present disclosure is schematically illustrated. At a first processing step S1, a first carrier wafer 601 is provided, which may comprise a circular wafer or a polygonal wafer such as a rectangular wafer. In embodiments in which the first carrier wafer 601 comprises a circular wafer, the diameter of the first carrier wafer 601 may be, for example, 200 mm, 300 mm, 450 mm, etc. Generally, the first carrier wafer 601 may comprise a semiconductor wafer, an insulating wafer, a conductive wafer, or a composite wafer having sufficient mechanical strength to support additional wafers to be subsequently attached thereto. The thickness of the first carrier wafer 601 may be in a range from 500 microns to 2 mm, although lesser and greater thicknesses may also be used. In one embodiment, the first carrier wafer 601 may comprise a commercially available silicon wafer.

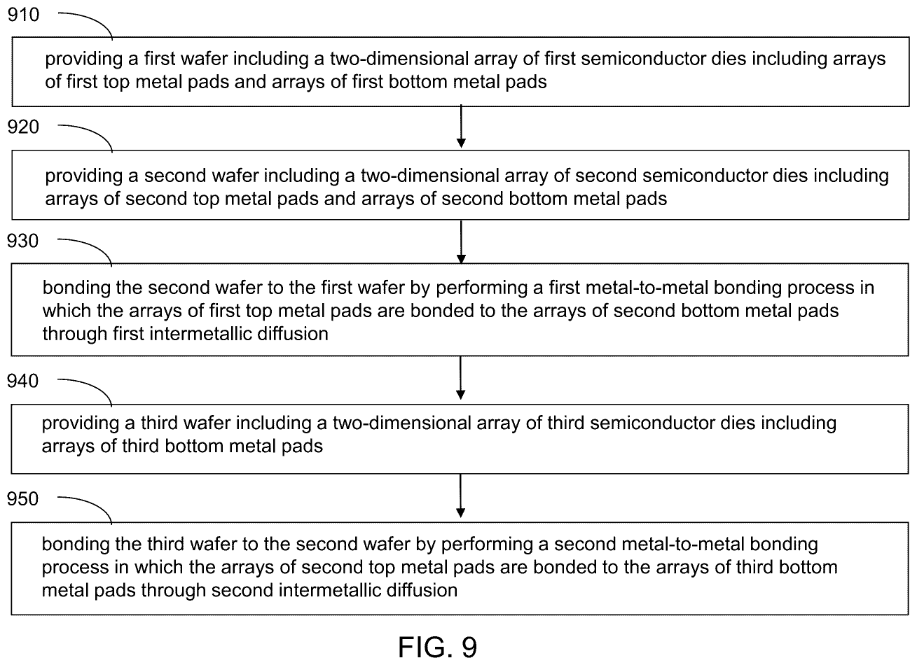

Referring to a first auxiliary processing step A1 (and also step 910 in FIG. 9 discussed below), a first wafer 100 is provided. The first wafer 100 comprises a two-dimensional array of first semiconductor dies 70. Each of the first semiconductor dies 70 comprises a respective array of top metal bonding pads configured for metal-to-metal bonding. As used herein, metal-to-metal bonding refers to a bonding method in which two sets of metal bonding pads provided in two semiconductor dies may be brought into direct contact with each other and may be annealed at an elevated temperature to induce intermetallic diffusion of a metal across each interface between mating pairs of the metal bonding pads to a degree that provides bonding between the mating pairs of the metal bonding pads. Metal-to-metal bonding does not use any intermediary material such as a solder material. Rather, the material diffusion of the metal in the mating pairs of metal bonding pads into each other causes bonding between the mating pairs of metal bonding pads. Typical materials that may be used for metal-to-metal bonding include copper, copper alloys, nickel, aluminum, silver, gold, etc.

Generally, the first semiconductor dies 70 may comprise any type of semiconductor dies known in the art. For example, the first semiconductor dies 70 may comprise logic dies, system-on-chip dies, memory dies, etc.

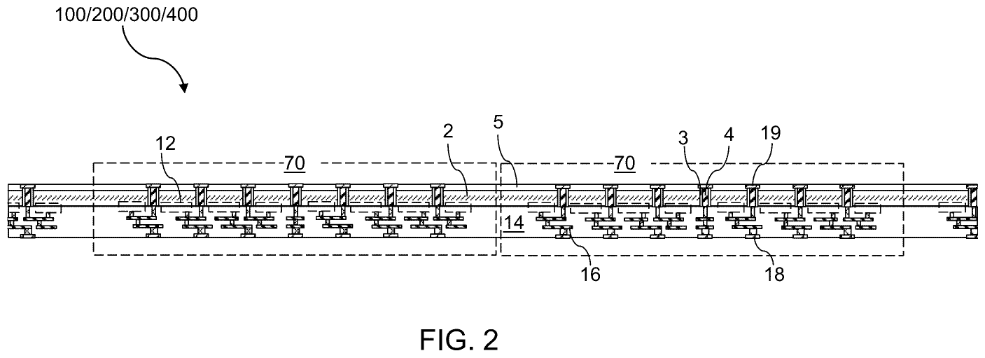

Referring to FIG. 2, an example of a first wafer 100 that may be provided at the first auxiliary processing step A1 in FIG. 1 is illustrated. In this example, the first wafer 100 may comprise a semiconductor-based wafer including a semiconductor substrate 2 that continuously extends over an entire area of the first wafer 100 as a single contiguous structure. As used herein, a semiconductor-base wafer refers to a wafer including a single contiguous semiconductor substrate having a same lateral extent as the wafer. In this embodiment, the first wafer 100 as illustrated in FIG. 2 may be provided, for example, by providing a semiconductor substrate having a thickness (such as a thickness in a range from 500 microns to 1 mm), by forming vertically-extending via cavities having a depth in a range from 5 microns to 30 microns in an upper portion of the semiconductor substrate and filling the vertically-extending via cavities with combinations of an insulating spacer 3 and a through-substrate via (TSV) structure 4, by forming semiconductor devices 12 on a top surface of, and/or within an upper portion of, the semiconductor substrate, by forming metal interconnect structures 16 and front metal bonding pads 18 formed within dielectric material layers 14, thinning the semiconductor substrate from the backside to provide the semiconductor substrate 2 as illustrated in FIG. 2, and by forming backside metal bonding pads 19 within a backside insulating layers 5 on the backside of the semiconductor substrate 2.

The thickness of the semiconductor substrate 2 after thinning may be in a range from 5 microns to 30 microns, and each of the backside metal bonding pads 19 may be formed on a respective one of the TSV structures 4. Electrically conductive paths may be formed between the front metal bonding pads 18 and the backside metal bonding pads 19. Each such electrically conductive path may comprise a respective one of the TSV structures 4. The first wafer 100 may comprise a two-dimensional periodic repetition of semiconductor dies 70. The semiconductor dies 70 within the first wafer 100 are referred to as first semiconductor dies 70. The first semiconductor dies 70 are interconnected to one another, and each of the first semiconductor dies 70 comprises a respective portion of the semiconductor substrate 2, which continuously extends over the entire area of the first wafer 100.

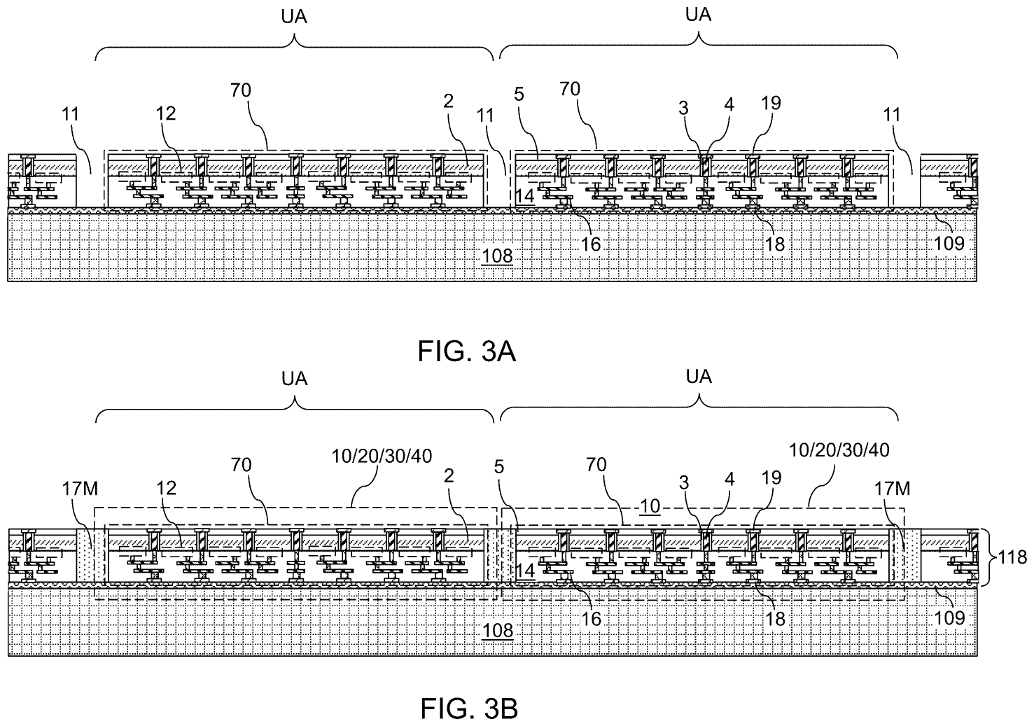

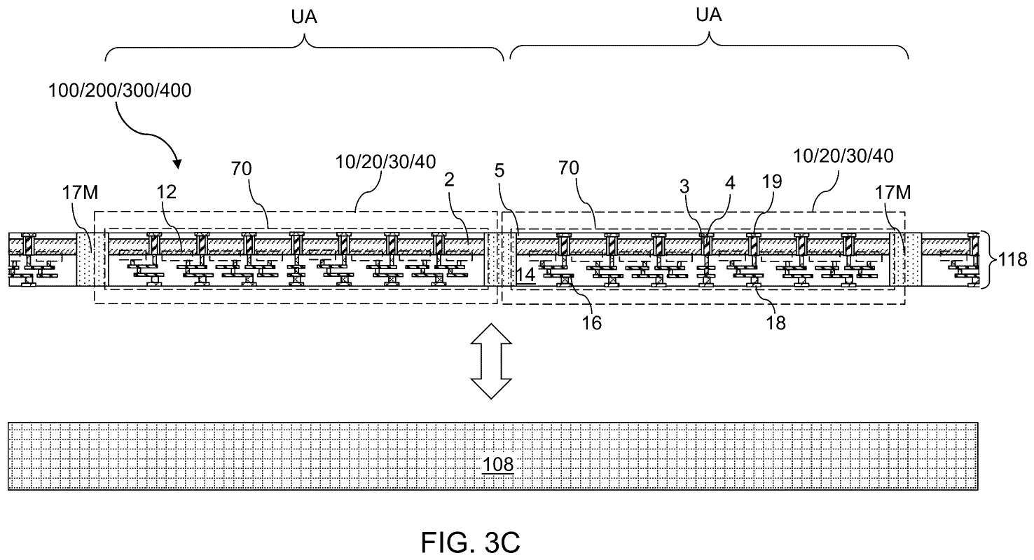

Alternatively, the first wafer 100 provided at the first auxiliary processing step A1 illustrated in FIG. 1 may comprise a reconstituted wafer. FIGS. 3A-3C are sequential schematic vertical cross-sectional views of a first exemplary structure during formation of a first reconstituted wafer 118 that may be used as the first wafer 100.

Referring to FIG. 3A, the first exemplary structure comprises a carrier substrate 108, a first adhesive layer 109 formed on a top surface of the carrier substrate 108, and a two-dimensional array of semiconductor dies 70 that are attached to the first adhesive layer 109. The carrier substrate 108 may include an optically transparent substrate such as a glass substrate or a sapphire substrate. The carrier substrate 108 may have a circular shape or a polygonal shape in a top-down view. In embodiments in which the carrier substrate 108 has a circular shape in the top-down view, the diameter of the carrier substrate 108 may be in a range from 150 mm to 450 mm, although lesser and greater diameters may be used. In addition, the thickness of the carrier substrate 108 may be in a range from 500 microns to 2,000 microns, although lesser and greater thicknesses may also be used. Alternatively, the carrier substrate 108 may be provided in a rectangular panel format. The dimensions of the first carrier in such alternative embodiments may be substantially the same.

The first adhesive layer 109 may be applied to the front-side surface of the carrier substrate 108. In one embodiment, the first adhesive layer 109 may be a light-to-heat conversion (LTHC) layer. The LTHC layer may be a solvent-based coating applied using a spin coating method. The LTHC layer may convert ultraviolet light to heat, which may cause the material of the LTHC layer to lose adhesion. Alternatively, the first adhesive layer 109 may include a thermally decomposing adhesive material. For example, the first adhesive layer 109 may include an acrylic pressure-sensitive adhesive that decomposes at an elevated temperature. The debonding temperature of the thermally decomposing adhesive material may be in a range from 150 degrees to 200 degrees Celsius.

The first semiconductor dies 70 may be attached to the first adhesive layer 109 in a two-dimensional periodic pattern, i.e., as a two-dimensional periodic array of first semiconductor dies 70. The area of the repetition unit is herein referred to as a unit area UA. Each first semiconductor die 70 may comprise a semiconductor substrate 2, an array of through-substrate via (TSV) structures 4, an array of insulating spacers 3, semiconductor devices 12 formed on a top side of the semiconductor substrate 2, metal interconnect structures 16 and front metal bonding pads 18 that are formed within dielectric material layers 14, a backside insulating layer 5, and backside metal bonding pads 19 formed within the backside insulating layer 5 and contacting a backside surface of a respective one of the TSV structures 4. In one embodiment, the first semiconductor dies 70 may be provided by dicing a wafer having substantially the same structure as the first wafer 100 described above into discrete semiconductor dies. The first semiconductor dies 70 may comprise logic dies, system-on-chip (SoC) dies, memory dies, or any other type of semiconductor dies known in the art. Gaps 11 between first semiconductor dies 70 attached to the first adhesive layer 109 in a two-dimensional periodic pattern may provide spacing and isolation between neighboring pairs of first semiconductor dies 70.

Referring to FIG. 3B, a molding compound may be applied to the gaps 11 between neighboring pairs of semiconductor dies 70. The molding compound may include an epoxy-containing compound that may be hardened (i.e., cured) to provide a dielectric material portion having sufficient stiffness and mechanical strength. The molding compound may include epoxy resin, hardener, silica (as a filler material), and other additives. The molding compound may be provided in a liquid form or in a solid form depending on the viscosity and flowability. Liquid molding compound provides better handling, good flowability, less voids, better fill, and less flow marks. Solid molding compound provides less cure shrinkage, better stand-off, and less die drift. A high filler content (such as 85% in weight) within an molding compound may shorten the time in mold, lower the mold shrinkage, and reduce the mold warpage. Uniform filler size distribution in the molding compound may reduce flow marks, and may enhance flowability. The curing temperature of the molding compound may be lower than the release (debonding) temperature of the first adhesive layer 109 in embodiments in which the adhesive layer includes a thermally debonding material. For example, the curing temperature of the molding compound may be in a range from 125° C. to 150° C.

The molding compound may be cured at a curing temperature to form an molding compound matrix 17M that laterally surrounds the two-dimensional array of semiconductor dies 70. The molding compound matrix 17M includes a plurality of molding compound die frames that are interconnected to one another. Each molding compound die frame is a portion of the molding compound matrix 17M that is located within an area of a repetition unit within a two-dimensional periodic array of structures overlying the carrier substrate 108. Thus, each molding compound die frame laterally surrounds and embeds a respective semiconductor die 70. Young's modulus of pure epoxy is about 3.35 GPa, and Young's modulus of the molding compound may be higher than Young's modulus of pure epoxy by adding additives. Young's modulus of molding compound may be greater than 3.5 GPa. In some embodiments, suitable alternative molding materials may be used for the molding compound matrix 17M.

Portions of the molding compound matrix 17M that overlies the horizontal plane including the top surfaces of the semiconductor dies 70 may be removed by a planarization process. For example, the portions of the molding compound matrix 17M that overlies the horizontal plane may be removed using a chemical mechanical planarization (CMP). The combination of the remaining portion of the molding compound matrix 17M and the semiconductor dies 70 comprises a reconstituted wafer 118. Each portion of the molding compound matrix 17M located within a unit area UA constitutes an molding compound die frame.

Referring to FIG. 3C, the first adhesive layer 109 may be decomposed by ultraviolet radiation or by a thermal anneal at a debonding temperature. In embodiments in which the carrier substrate 108 includes an optically transparent material and the first adhesive layer 109 includes an LTHC layer, the first adhesive layer 109 may be decomposed by irradiating ultraviolet light through the transparent carrier substrate. The LTHC layer may be absorb the ultraviolet radiation and generate heat, which decomposes the material of the LTHC layer and cause the transparent carrier substrate 108 to be detached from the reconstituted wafer 118. In embodiments in which the first adhesive layer 109 includes a thermally decomposing adhesive material, a thermal anneal process at a debonding temperature may be performed to detach the carrier substrate 108 from the reconstituted wafer 118. The detached reconstituted wafer 118 may be used as the first wafer 100 as provided at the auxiliary processing step A1 in FIG. 1.

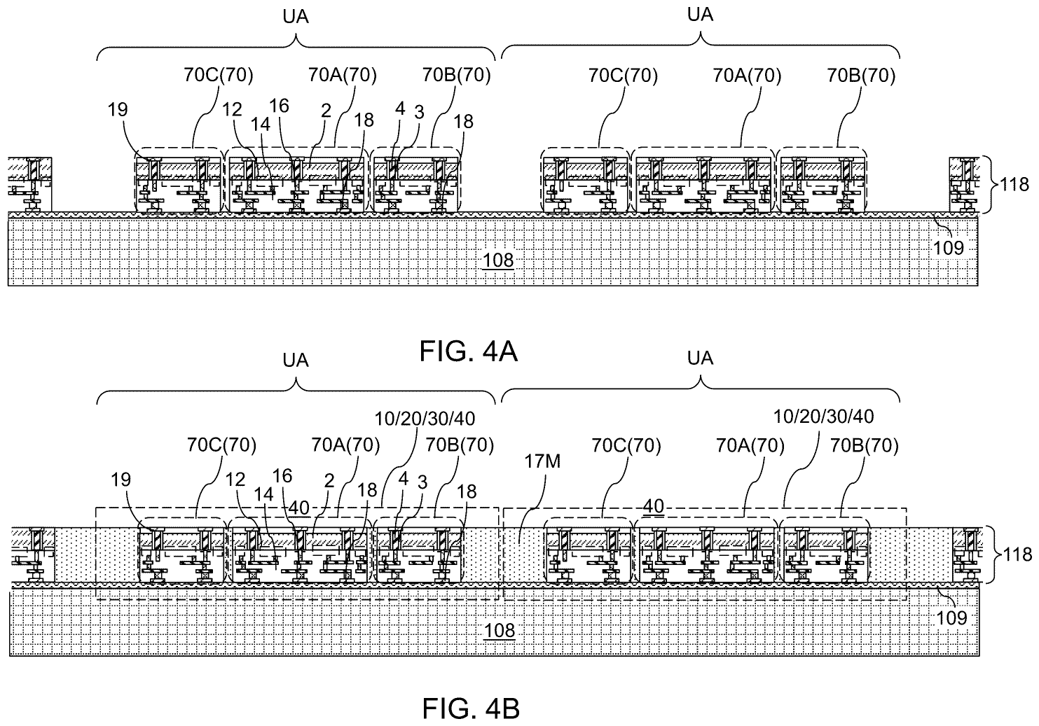

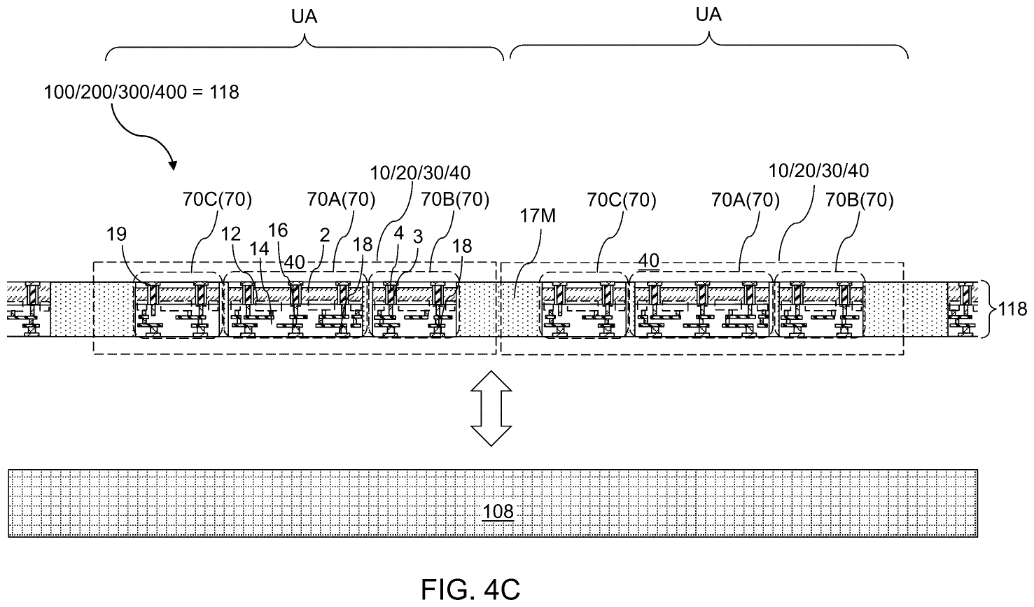

In some embodiments, a reconstituted wafer 118 used as the first wafer 100 at the first auxiliary processing step A1 illustrated in FIG. 1 may comprise a plurality of semiconductor dies 70 and/or at least one optional dummy die within each unit area UA. FIGS. 4A-4C are sequential schematic vertical cross-sectional views of a second exemplary structure during formation of a second reconstituted wafer 118 that may be used as the first wafer 100.

Referring to FIG. 4A, the second exemplary structure may be derived from the first exemplary structure illustrated in FIG. 3A by using a plurality of semiconductor dies (70A, 70B, 70C) per unit area UA in lieu of a single semiconductor die 70 per unit area UA in the first exemplary structure of FIG. 3A. In this embodiment, the plurality of semiconductor dies (70A, 70B, 70C) within each unit area UA comprises at least a first-type semiconductor die 70A, a second-type semiconductor die 70B, and optionally a third-type semiconductor die 70C and additional semiconductor dies (not illustrated). Each of the semiconductor dies 70 within a unit area UA may comprise a logic die, a system-on-chip (SoC) die, a memory die, a bridge die, a passive device die, or any other type of semiconductor die known in the art. Alternatively, one or more of the plurality of semiconductor dies (70A, 70B, 70C) may be replaced with a dummy die, which is a non-functional die that is used for the sake of facilitating a planarization process that planarizes the molding compound matrix 17M. For example, one or more of the second-type semiconductor die 70B, the optional third-type semiconductor die 70C, and the optional additional semiconductor dies (not illustrated) may be replaced with a dummy die. Such embodiments are expressly contemplated herein.

Each of the plurality of semiconductor dies (70A, 70B, 70C) may comprise a semiconductor substrate 2, an optional array of through-substrate via (TSV) structures 4, an optional array of insulating spacers 3, optional semiconductor devices 12 formed on a top side of the semiconductor substrate 2, metal interconnect structures 16 and front metal bonding pads 18 that are formed within dielectric material layers 14, a backside insulating layer 5, and backside metal bonding pads 19 formed within the backside insulating layer 5 and contacting a backside surface of a respective one of the TSV structures 4. At least one, a plurality, and/or each, of the plurality of semiconductor dies (70A, 70B, 70C) may comprise a respective array of through-substrate via (TSV) structures 4 and a respective array of insulating spacers 3. At least one, a plurality, and/or each, of the plurality of semiconductor dies (70A, 70B, 70C) may comprise a respective set of semiconductor devices 12.

Referring to FIG. 4B, the processing steps described with reference to FIG. 3B may be performed to form a molding compound matrix 17M that laterally surrounds each semiconductor die 70 over the carrier substrate 108.

Referring to FIG. 4C, the processing steps described with reference to FIG. 3C may be performed to detach the reconstituted wafer 118 from the carrier substrate 108. The reconstituted wafer 118 may be used as the first wafer 100 as provided at the auxiliary processing step A1 in FIG. 1.

Referring to a second processing step S2 illustrated in FIG. 1 (and also steps 920 and 930 in FIG. 9 discussed below), the first wafer 100 may be attached to the top surface of the first carrier wafer 601, for example, using an adhesive layer (not illustrated). The adhesive layer may comprise an ultraviolet-decomposable adhesive material or a thermally-decomposable adhesive material. Generally, a first wafer 100 including a two-dimensional array of first semiconductor dies 70 may be attached to the first carrier wafer 601. The two-dimensional array of first semiconductor dies 70 comprises arrays of first top metal bonding pads that are physically exposed, and arrays of first bottom metal bonding pads that face a top surface of a first carrier wafer 601 and in contact with the adhesive layer.

In one embodiment, the arrays of first top metal bonding pads comprise arrays of front metal bonding pads 18 that are formed within dielectric material layers 14, and the arrays of first bottom metal bonding pads comprise arrays of backside metal bonding pads 19 that are formed within a respective backside insulating layer 5. In this embodiment, the first semiconductor dies 70 are positioned such that the front metal bonding pads 18 face upward and the backside metal bonding pads 19 face downward.

In another embodiment, the arrays of first top metal bonding pads comprise arrays of backside metal bonding pads 19 that are formed within a respective backside insulating layer 5, and the arrays of first bottom metal bonding pads comprise arrays of front metal bonding pads 18 that are formed within dielectric material layers 14. In this embodiment, the first semiconductor dies 70 may be positioned such that the backside metal bonding pads 19 face upward and the front metal bonding pads 18 face downward.

Generally, a first wafer 100 including a two-dimensional array of first semiconductor dies 70 including arrays of first top metal bonding pads (18, 19) and arrays of first bottom metal bonding pads (18, 19) may be attached to a top surface of a first carrier wafer 601. The first wafer 100 may comprise a semiconductor-based wafer illustrated in FIG. 2, or may comprise a reconstituted wafer 118 illustrated in FIG. 3C or 4C.

Referring to a second auxiliary processing step A2 illustrated in FIG. 1, a second wafer 200 is provided (see also step 920 in FIG. 9). The second wafer 200 includes a two-dimensional array of second semiconductor dies 70 including arrays of second top metal bonding pads and arrays of second bottom metal bonding pads. Generally, the second wafer 200 may have a semiconductor-based wafer illustrated in FIG. 2, or may be a reconstituted wafer 118 illustrated in FIGS. 3C and 4C. In other words, any of the semiconductor-based wafer illustrated in FIG. 2 or the reconstituted wafers 118 illustrated in FIGS. 3C and 4C may be used for the second wafer 200. Therefore, any type of wafer that may be used to the first wafer 100 may be used as the second wafer 200.

Referring to a third processing step S3 illustrated in FIG. 1 (see also step 930 in FIG. 9), the second wafer 200 may be bonded to the first wafer 100 by performing a first metal-to-metal bonding process. The arrays of first top metal bonding pads (18 or 19) in the first wafer 100 are bonded to the arrays of second bottom metal bonding pads (18 or 19) in the second wafer 200 through first intermetallic diffusion. In one embodiment, the first top metal bonding pads (18 or 19) in the first wafer 100 may be copper bonding pads, the arrays of second bottom metal bonding pads (18 or 19) in the second wafer 200 may be additional copper bonding pads, and the metal-to-metal bonding may be copper-to-copper bonding. Additionally, dielectric-to-dielectric bonding such as silicon oxide-to-silicon oxide bonding may be performed between a topmost insulating layer of the first wafer 100 and a bottommost insulating layer of the second wafer 200.

In one embodiment, the first top metal bonding pads in the first wafer 100 may comprise first front metal bonding pads 18 formed within the dielectric material layers 14 of the first wafer 100, and the second bottom metal bonding pads in the second wafer 200 may comprise second backside metal bonding pads 19 formed within the backside insulating layer 5 of the second wafer 200. In this embodiment, a dielectric-to-dielectric bonding between the dielectric material layers 14 of the first wafer 100 and the backside insulating layer 5 of the second wafer 200 may be performed concurrently with the metal-to-metal bonding.

In another embodiment, the first top metal bonding pads in the first wafer 100 may comprise first front metal bonding pads 18 formed within the dielectric material layers 14 of the first wafer 100, and the second bottom metal bonding pads in the second wafer 200 may comprise second front metal bonding pads 18 formed within the dielectric material layers 14 of the second wafer 200. In this embodiment, a dielectric-to-dielectric bonding between the dielectric material layers 14 of the first wafer 100 and the dielectric material layers 14 of the second wafer 200 may be performed concurrently with the metal-to-metal bonding.

In yet another embodiment, the first top metal bonding pads in the first wafer 100 may comprise first backside metal bonding pads 19 formed within the backside insulating layer 5 of the first wafer 100, and the second bottom metal bonding pads in the second wafer 200 may comprise second backside metal bonding pads 19 formed within the backside insulating layer 5 of the second wafer 200. In this embodiment, a dielectric-to-dielectric bonding between the backside insulating layer 5 of the first wafer 100 and the backside insulating layer 5 of the second wafer 200 may be performed concurrently with the metal-to-metal bonding.

In still another embodiment, the first top metal bonding pads in the first wafer 100 may comprise first backside metal bonding pads 19 formed within the backside insulating layer 5 of the first wafer 100, and the second bottom metal bonding pads in the second wafer 200 may comprise second front metal bonding pads 18 formed within the dielectric material layers 14 of the second wafer 200. In this embodiment, a dielectric-to-dielectric bonding between the backside insulating layer 5 of the first wafer 100 and the dielectric material layers 14 of the second wafer 200 may be performed concurrently with the metal-to-metal bonding.

Generally, the array of first semiconductor dies 70 in the first wafer 100 and the array of second semiconductor dies 70 in the second wafer 200 may have the same shape for each unit area UA, and may have the same two-dimensional periodicity. Generally, a second wafer 200 including a two-dimensional array of second semiconductor dies 70 including arrays of second top metal bonding pads (18 or 19) and arrays of second bottom metal bonding pads (18 or 19) may be attached to the first wafer 100 by performing a first metal-to-metal bonding process in which the arrays of first top metal bonding pads (18 or 19) are bonded to the arrays of second bottom metal bonding pads (18, 19) through first intermetallic diffusion.

Referring to a third auxiliary processing step A3 illustrated in FIG. 1, a third wafer 300 is provided (see also step 940 in FIG. 9). The third wafer 300 includes a two-dimensional array of third semiconductor dies 70 including arrays of third top metal bonding pads and arrays of third bottom metal bonding pads. Generally, the third wafer 300 may have a semiconductor-based wafer illustrated in FIG. 2, or may be a reconstituted wafer 118 illustrated in FIGS. 3C and 4C. In other words, any of the semiconductor-based wafer illustrated in FIG. 2 or the reconstituted wafers 118 illustrated in FIGS. 3C and 4C may be used for the third wafer 300. Therefore, any type of wafer that may be used to the second wafer 200 may be used as the third wafer 300.

Referring to a fourth processing step S4 illustrated in FIG. 1 (see also step 950 in FIG. 9), the third wafer 300 may be bonded to the second wafer 200 by performing a second metal-to-metal bonding process. The arrays of second top metal bonding pads (18 or 19) in the second wafer 200 are bonded to the arrays of third bottom metal bonding pads (18 or 19) in the third wafer 300 through second intermetallic diffusion. In one embodiment, the second top metal bonding pads (18 or 19) in the second wafer 200 may be copper bonding pads, the arrays of third bottom metal bonding pads (18 or 19) in the third wafer 300 may be additional copper bonding pads, and the metal-to-metal bonding may be copper-to-copper bonding. Additionally, dielectric-to-dielectric bonding such as silicon oxide-to-silicon oxide bonding may be performed between a topmost insulating layer of the second wafer 200 and a bottommost insulating layer of the third wafer 300.

In one embodiment, the second top metal bonding pads in the second wafer 200 may comprise second front metal bonding pads 18 formed within the dielectric material layers 14 of the second wafer 200, and the third bottom metal bonding pads in the third wafer 300 may comprise third backside metal bonding pads 19 formed within the backside insulating layer 5 of the third wafer 300. In this embodiment, a dielectric-to-dielectric bonding between the dielectric material layers 14 of the second wafer 200 and the backside insulating layer 5 of the third wafer 300 may be performed concurrently with the metal-to-metal bonding.

In another embodiment, the second top metal bonding pads in the second wafer 200 may comprise second front metal bonding pads 18 formed within the dielectric material layers 14 of the second wafer 200, and the third bottom metal bonding pads in the third wafer 300 may comprise third front metal bonding pads 18 formed within the dielectric material layers 14 of the third wafer 300. In this embodiment, a dielectric-to-dielectric bonding between the dielectric material layers 14 of the second wafer 200 and the dielectric material layers 14 of the third wafer 300 may be performed concurrently with the metal-to-metal bonding.

In yet another embodiment, the second top metal bonding pads in the second wafer 200 may comprise second backside metal bonding pads 19 formed within the backside insulating layer 5 of the second wafer 200, and the third bottom metal bonding pads in the third wafer 300 may comprise third backside metal bonding pads 19 formed within the backside insulating layer 5 of the third wafer 300. In this embodiment, a dielectric-to-dielectric bonding between the backside insulating layer 5 of the second wafer 200 and the backside insulating layer 5 of the third wafer 300 may be performed concurrently with the metal-to-metal bonding.

In still another embodiment, the second top metal bonding pads in the second wafer 200 may comprise second backside metal bonding pads 19 formed within the backside insulating layer 5 of the second wafer 200, and the third bottom metal bonding pads in the third wafer 300 may comprise third front metal bonding pads 18 formed within the dielectric material layers 14 of the third wafer 300. In this embodiment, a dielectric-to-dielectric bonding between the backside insulating layer 5 of the second wafer 200 and the dielectric material layers 14 of the third wafer 300 may be performed concurrently with the metal-to-metal bonding.

Generally, the array of second semiconductor dies 70 in the second wafer 200 and the array of third semiconductor dies 70 in the third wafer 300 may have the same shape for each unit area UA, and may have the same two-dimensional periodicity. Generally, a third wafer 300 including a two-dimensional array of third semiconductor dies 70 including arrays of third top metal bonding pads (18 or 19) and arrays of third bottom metal bonding pads (18 or 19) may be attached to the second wafer 200 by performing a second metal-to-metal bonding process in which the arrays of second top metal bonding pads (18 or 19) are bonded to the arrays of third bottom metal bonding pads (18, 19) through second intermetallic diffusion.

Referring to a fourth auxiliary processing steps A4, at least one semiconductor-based wafer including a plurality of semiconductor dies 70 may be provided. In an illustrative example, a first semiconductor-based wafer including a two-dimensional array of first-type semiconductor dies 70A and a second semiconductor-based wafer including a two-dimensional array of second-type semiconductor dies 70B may be provided. Optionally, at least one additional semiconductor-based wafer (not illustrated) including a two-dimensional array of additional semiconductor dies (such as third-type semiconductor dies) may be provided. Each of the first-type semiconductor dies 70A, the second-type semiconductor dies 70B, third-type semiconductor dies, etc. may have a respective shape that is smaller than the shape of the unit area UA within the first wafer 100, the second wafer 200, and the third wafer 300.

Referring to fifth auxiliary processing steps A5, the semiconductor-based wafers may be diced along dicing channels to provide various types of semiconductor dies 70, which may comprise first-type semiconductor dies 70A, second-type semiconductor dies 70B, optional third-type semiconductor dies (not illustrated), etc. Generally, each of the first-type semiconductor dies 70A, second-type semiconductor dies 70B, optional third-type semiconductor dies, etc. may independently comprise any type of semiconductor dies known in the art, and may comprise, for example, a logic die, a system-on-chip (SoC) die, a memory die, a bridge die, an integrated passive device die, etc.

In one embodiment, each semiconductor die (70A, 70B, 70C) within the set of multiple semiconductor dies 70 may comprise a semiconductor substrate 2, an optional array of through-substrate via (TSV) structures 4, an optional array of insulating spacers 3, optional semiconductor devices 12 formed on a top side of the semiconductor substrate 2, metal interconnect structures 16 and front metal bonding pads 18 that are formed within dielectric material layers 14, an optional backside insulating layer 5, and optional backside metal bonding pads 19 formed within the optional backside insulating layer 5 and contacting a backside surface of a respective one of the optional TSV structures 4. Generally, in embodiments in which TSV structures 4 are present in a semiconductor die (70A, 70B, 70C), a backside insulating layer 5 and backside metal bonding pads 19 are present in the semiconductor die (70A, 70B, 70C).

Referring to a fifth processing step S5, a set of multiple semiconductor dies 70, such as a combination of a first-type semiconductor die 70A, a second-type semiconductor die 70B, and a third-type semiconductor die 70C may be bonded to at least one third semiconductor die 70 within a respective unit area UA in the third wafer 300. Each semiconductor die (70A, 70B, 70C) within the set of multiple semiconductor dies 70 may be bonded to the at least one third semiconductor die 70 within the respective unit area UA by metal-to-metal bonding. Thus, no adhesive layer is used at this processing step.

Each semiconductor die (70A, 70B, 70C) within the set of multiple semiconductor dies 70 may be bonded to a respective set of physically exposed metal bonding pads (18 or 19) of a respective third semiconductor die 70 in the third wafer 300 through the front metal bonding pads 18 of the respective semiconductor die (70A, 70B, 70C), or may be bonded to the respective set of physically exposed metal bonding pads (18 or 19) of the respective third semiconductor die 70 in the third wafer 300 through backside metal bonding pads 19 (if present) of the respective semiconductor die (70A, 70B, 70C).

A two-dimensional periodic array of sets of semiconductor dies (70A, 70B, 70C) may be positioned over the third wafer 300. Subsequently, the two-dimensional periodic array of sets of semiconductor dies (70A, 70B, 70C) may be pressed against the third wafer 300, and the assembly of the first carrier wafer 601, the first wafer 100, the second wafer 200, the third wafer 300, and the two-dimensional periodic array of sets of semiconductor dies (70A, 70B, 70C) may be annealed at an elevated temperature, for example, in a range from 200 degrees Celsius to 400 degrees Celsius, to provide metal-to-metal bonding between the two-dimensional periodic array of sets of semiconductor dies (70A, 70B, 70C) and the two-dimensional array of third semiconductor dies 70. Optionally, dielectric-to-dielectric bonding, such as silicon oxide-to-silicon oxide bonding, may be used between the physically exposed dielectric layer of the third wafer 300 and the bottom-side dielectric layers of the semiconductor dies (70A, 70B, 70C).

Referring to a sixth processing step S6, the processing steps described with reference to FIGS. 4B and 4C may be performed to form a molding compound matrix around the two-dimensional arrays of sets of multiple semiconductor dies (70A, 70B, 70C). A fourth wafer 400 may be attached to the third wafer 300. The fourth wafer 400 may be a reconstituted wafer.

Generally, a fourth wafer 400 comprising a two-dimensional array of fourth semiconductor dies 70 including arrays of fourth bottom metal bonding pads (18, 19) may be attached to the third wafer 300 by performing a third metal-to-metal bonding process in which the arrays of third top metal bonding pads (18, 19) are bonded to the arrays of fourth bottom metal bonding pads (18, 19) through third intermetallic diffusion.

While the present disclosure is described using an embodiment in which the first wafer 100, the second wafer 200, and the third wafer 300 are provided prior to bonding to an underlying wafer and the fourth wafer 400 is assembled over the third wafer by attaching semiconductor dies (70A, 70B, 70C) individually using metal-to-metal bonding, each of the second wafer 200 and the third wafer 300 may be assembled over a respective underlying wafer by attaching second semiconductor dies 70 or third semiconductor dies 70 to the respective underlying wafer and by forming a molding compound matrix. Further, the fourth wafer 400 may be provided as a semiconductor-based wafer illustrated in FIG. 2, or as a reconstituted wafer illustrated in FIG. 3C or 4C. All such variations are expressly contemplated herein.

Further, embodiments in which any of the first wafer 100, the second wafer 200, the third wafer 300, or the fourth wafer 400 is omitted are expressly contemplated herein. In addition, embodiments are expressly contemplated in which at least one additional wafer (not illustrated) including a respective two-dimensional periodic array of semiconductor dies is attached to, and is bonded to, the bonded assembly of the first carrier wafer 601, the first wafer 100, the second wafer 200, the third wafer 300, and the fourth wafer 400. Generally, the present disclosure may be practiced with at least three wafers each including a respective two-dimensional periodic array of semiconductor dies 70.

It should be noted that the ordinals such as “first,” “second,” “third,” and “fourth” are not parts of a name for an element, but are merely adjectives. As such, the first wafer 100 as described in the specification may be referred to as a first wafer, a second wafer, a third wafer, or as an i-th wafer in which i is an integer greater than 3. Likewise, the second wafer 200 as described in the specification may be referred to as a first wafer, a second wafer, a third wafer, or as a j-th wafer in which j is an integer greater than 3. Similarly, the third wafer 300 as described in the specification may be referred to as a first wafer, a second wafer, a third wafer, or as a k-th wafer in which k is an integer greater than 3. Likewise, the fourth wafer 400 as described in the specification may be referred to as a first wafer, a second wafer, a third wafer, or as an 1-th wafer in which 1 is an integer greater than 3.

Each unit area UA in the first wafer 100 may include only a single first semiconductor die 70 or a plurality of first semiconductor dies 70. Each unit area UA in the second wafer 200 may include only a single second semiconductor die 70 or a plurality of second semiconductor dies 70. Each unit area UA in the third wafer 300 may include only a single third semiconductor die 70 or a plurality of third semiconductor dies 70. Each unit area UA in the fourth wafer 400 may include only a single fourth semiconductor die 70 or a plurality of fourth semiconductor dies 70. In embodiments in which each unit area UA in any wafer (100, 200, 300, or 400) comprises a plurality of semiconductor dies 70, the plurality of semiconductor dies 70 may comprise a first-type semiconductor die 70A and a second-type semiconductor die 70B. In this embodiment, the semiconductor dies in such a wafer (100, 200, 300, 400) comprises first-type semiconductor dies 70A and second-type semiconductor dies 70B.

In an illustrative example, in embodiments in which each unit area UA the third wafer 300 comprises a first-type semiconductor die 70A and a second-type semiconductor die 70B, the third semiconductor dies 70 in the third wafer 300 comprises first-type semiconductor dies 70A and second-type semiconductor dies 70B. In this embodiment, the two-dimensional array of third semiconductor dies 70 comprises a two-dimensional periodic array of a repletion unit that includes a combination of a first-type semiconductor die 70A and a second-type semiconductor die 70B that is different from the first-type semiconductor die 70A. The same feature applies to each of the first wafer 100, the second wafer 200, the fourth wafer 400, and any additional wafer (if present) that includes an array of semiconductor dies 70.

In some embodiment, at least one of the first wafer 100, the second wafer 200, the third wafer 300, and the fourth wafer 400 may comprise a reconstituted wafer 118. In one embodiment, a first one of the first wafer 100, the second wafer 200, and the third wafer 300 comprises a reconstituted wafer in which a molding compound matrix 17M laterally surrounds a first two-dimensional array selected from the two-dimensional array of first semiconductor dies 70, the two-dimensional array of second semiconductor dies 70, and the two-dimensional array of third semiconductor dies 70. In one embodiment, a second one of the first wafer 100, the second wafer 200, and the third wafer 300 comprises an additional reconstituted wafer in which an additional molding compound matrix 17M laterally surrounds a second two-dimensional array selected from the two-dimensional array of first semiconductor dies 70, the two-dimensional array of second semiconductor dies 70, and the two-dimensional array of third semiconductor dies 70. In one embodiment, a third one of the first wafer 100, the second wafer 200, and the third wafer 300 comprises a yet additional reconstituted wafer in which a yet additional molding compound matrix 17M laterally surrounds a third two-dimensional array selected from the two-dimensional array of first semiconductor dies 70, the two-dimensional array of second semiconductor dies 70, and the two-dimensional array of third semiconductor dies 70.

In an illustrative example, the third wafer 300 comprises a reconstituted wafer in which the third semiconductor dies 70 are laterally surrounded by a molding compound matrix 17M. In a further illustrative example, the second wafer 200 comprises an additional reconstituted wafer in which the second semiconductor dies 70 are laterally surrounded by an additional molding compound matrix 17M. In a yet further illustrative example, the first wafer 100 comprises a yet additional reconstituted wafer in which the first semiconductor dies 70 are laterally surrounded by a yet additional molding compound matrix 17M.

In an illustrative example, the two-dimensional array of third semiconductor dies 70 in the third wafer 300 comprises a two-dimensional periodic array of a repletion unit that includes a combination of a first-type semiconductor die 70A and a second-type semiconductor die 70B that is different from the first-type semiconductor die 70A. In a further illustrative example, the two-dimensional array of second semiconductor dies 70 in the second wafer 200 comprises a two-dimensional periodic array of a repletion unit that includes a combination of an additional first-type semiconductor die 70A and an additional second-type semiconductor die 70B that is different from the first-type semiconductor die 70A. In a yet further illustrative example, the two-dimensional array of fourth semiconductor dies 70 in the fourth wafer 400 comprises a two-dimensional periodic array of a repletion unit that includes a combination of a yet additional first-type semiconductor die 70A and a yet additional second-type semiconductor die 70B that is different from the first-type semiconductor die 70A. The first-type semiconductor die 70A and the second-type semiconductor die 70B within a same unit area UA in a same wafer (100, 200, 300, 400) may be different from each other in design, size, and/or functionality.

Referring to a seventh processing step S7, a second carrier wafer 602 may be optionally attached to the topmost wafer (such as the fourth wafer 400) in the bonded assembly of the first carrier wafer 601 and at least three wafers (100, 200, 300, 400) including a respective two-dimensional periodic array of semiconductor dies 70. The second carrier wafer 602 may be attached to the topmost wafer, for example, through an adhesive layer (not illustrated). The second carrier wafer 602 may comprise any material that may be used for the first carrier wafer 601.

Referring to an eighth processing step S8, the first carrier wafer 601 may be detached from the assembly of at least three wafers (100, 200, 300, 400) and the optional second carrier wafer 602. For example, the adhesive layer located between the first carrier wafer 601 and the first wafer 100 may be decomposed by ultraviolet radiation or by a thermal anneal at a debonding temperature. In embodiments in which the first carrier wafer 601 includes an optically transparent material and the adhesive layer thereupon includes an LTHC layer, the adhesive layer may be decomposed by irradiating ultraviolet light through the transparent carrier substrate. In embodiments in which the adhesive layer includes a thermally decomposing adhesive material, a thermal anneal process may be performed at a debonding temperature (which is higher than the metal-to-metal bonding temperatures used to form the bonded assembly (100, 200, 300, optionally 400, optionally 602).

First bottom metal bonding pads of the first semiconductor dies 70 in the first wafer 100 may be physically exposed upon detaching the first carrier wafer 601 from the bonded assembly (100, 200, 300, optionally 400, optionally 602). The physically exposed first bottom metal bonding pads may comprise backside metal bonding pads 19 of the first semiconductor dies 70, or may comprise front metal bonding pads 18 of the first semiconductor dies 70. Arrays of solder material portions (not illustrated) may be attached to the arrays of first bottom metal bonding pads.

Referring to a ninth processing step S9, the bonded assembly (100, 200, 300, optionally 400, optionally 602) comprising at least the first wafer 100, the second wafer 200, and the third wafer 300 may be diced into a plurality of composite packages 80. Each of the composite packages 80 may comprise an assembly of a respective one (or more) of the first semiconductor dies 70, a respective one (or more) of the second semiconductor dies 70, a respective one (or more) of the third semiconductor dies 70, optionally a respective one (or more) of the fourth semiconductor dies 70, and optionally a respective handle substrate 60 which is a diced potion of the second carrier wafer 602 (in embodiments in which the second carrier wafer 602 is diced during the dicing step). Alternatively, the second carrier wafer 602 may de detached prior to the dicing step. In this embodiment, each of the composite packages 80 may comprise an assembly of a respective one (or more) of the first semiconductor dies 70, a respective one (or more) of the second semiconductor dies 70, a respective one (or more) of the third semiconductor dies 70, and optionally a respective one (or more) of the fourth semiconductor dies 70.

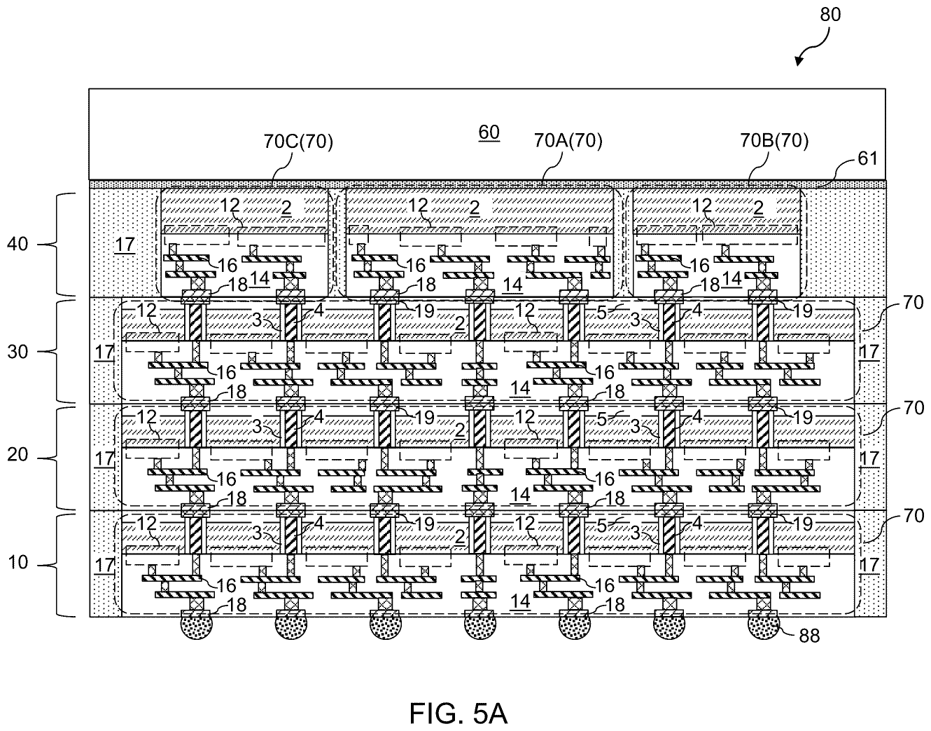

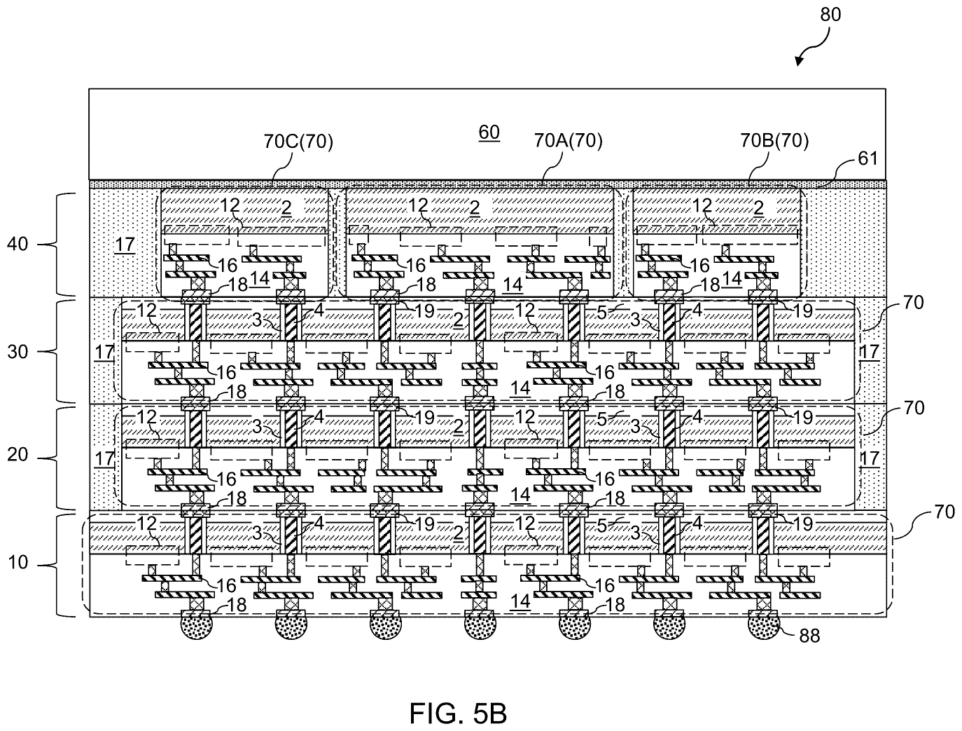

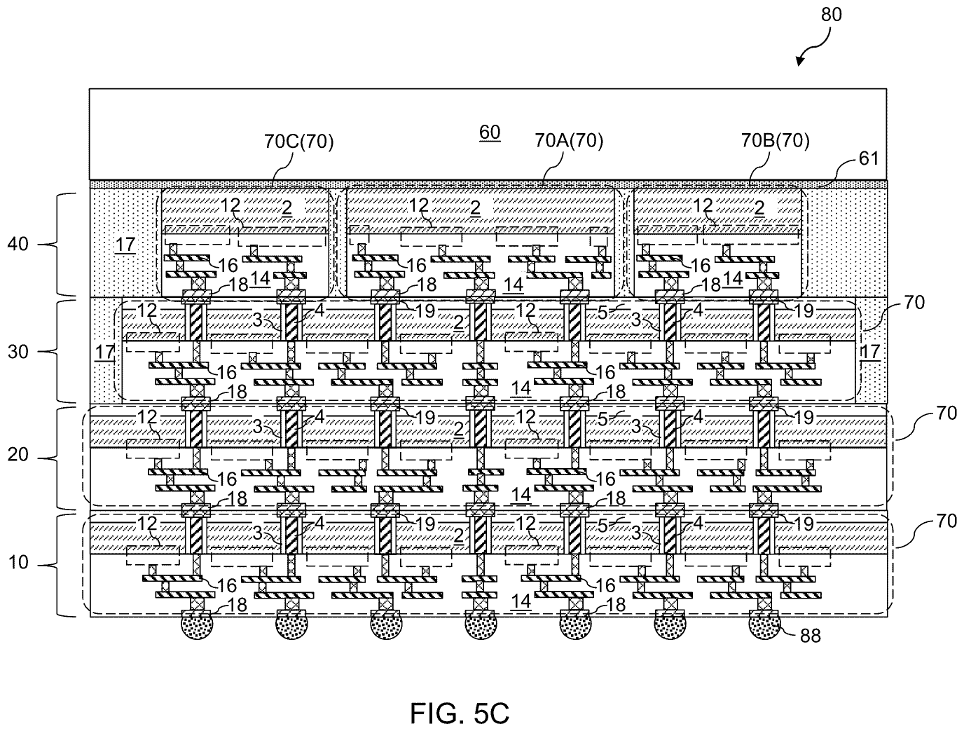

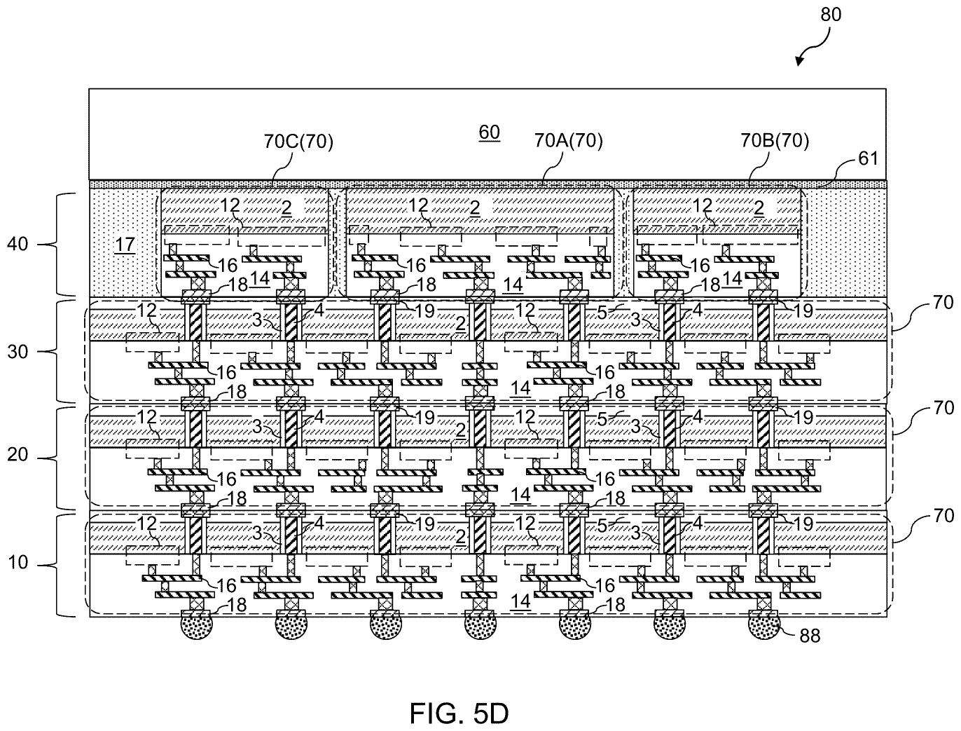

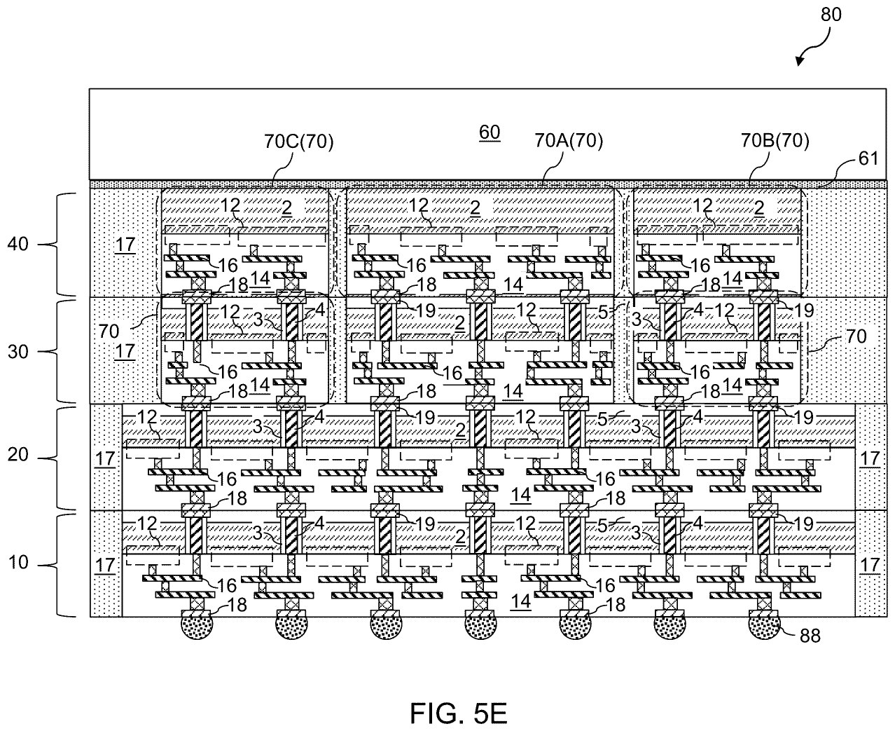

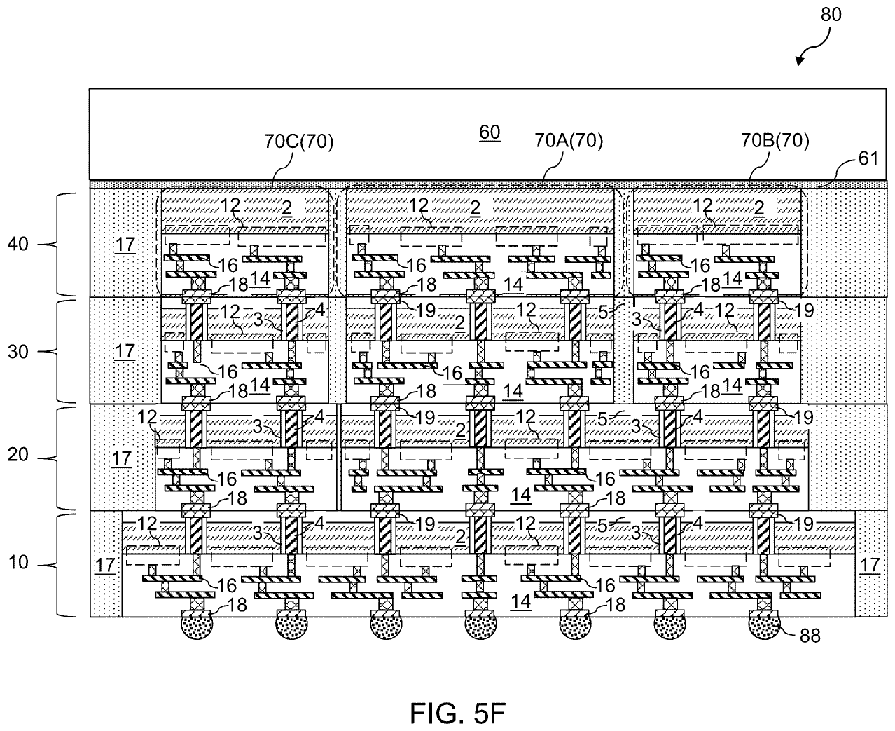

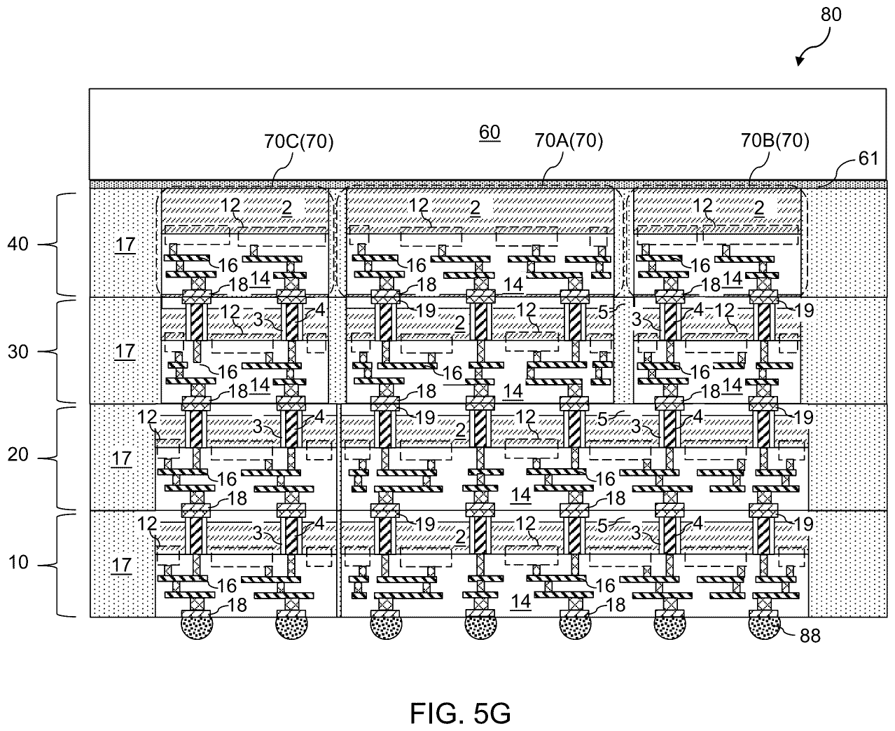

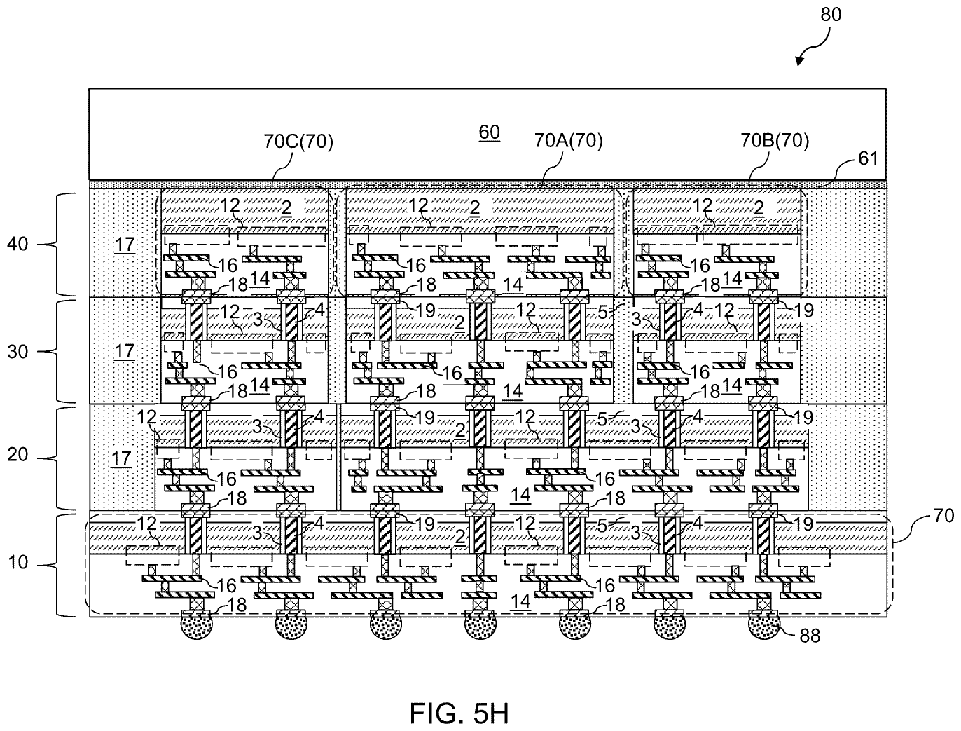

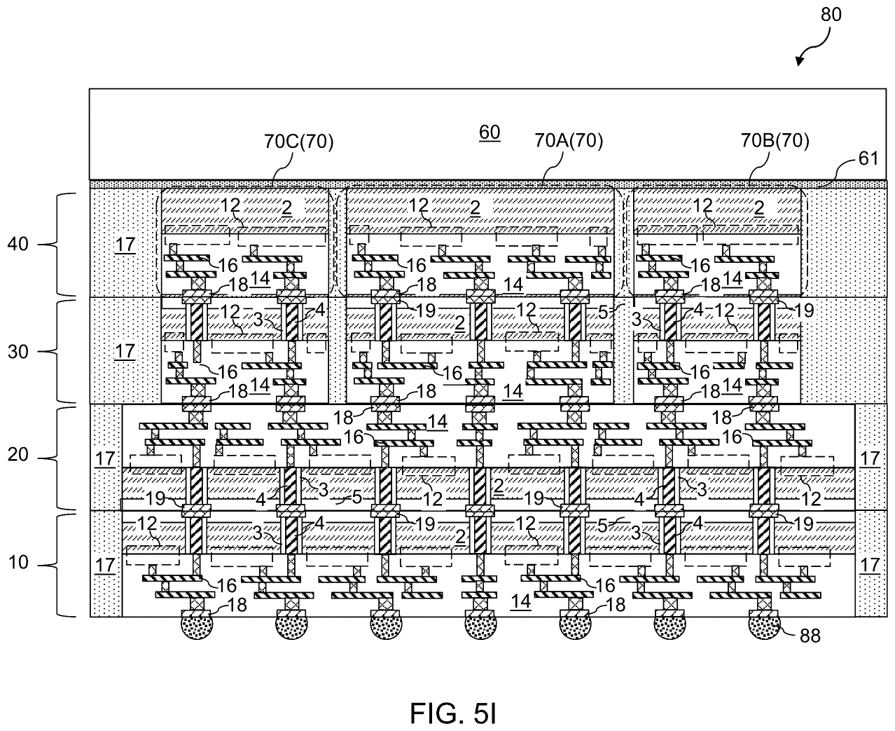

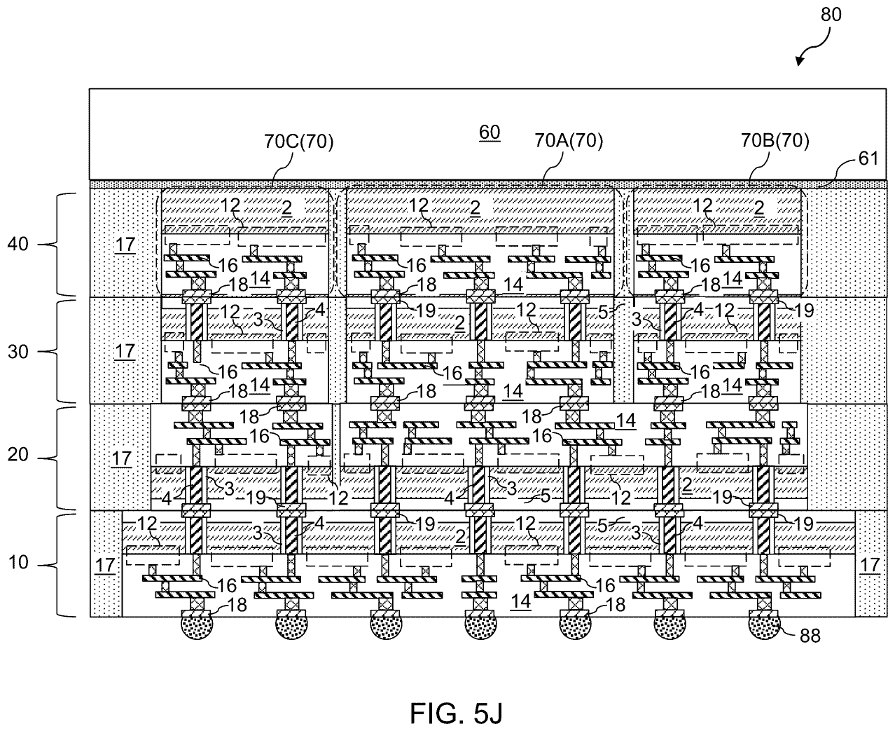

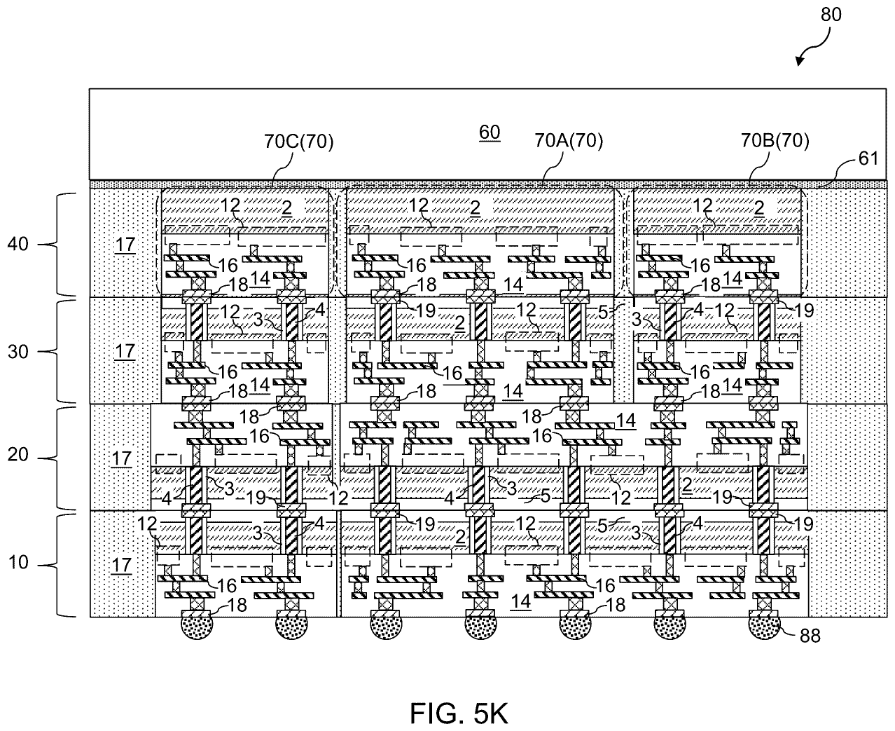

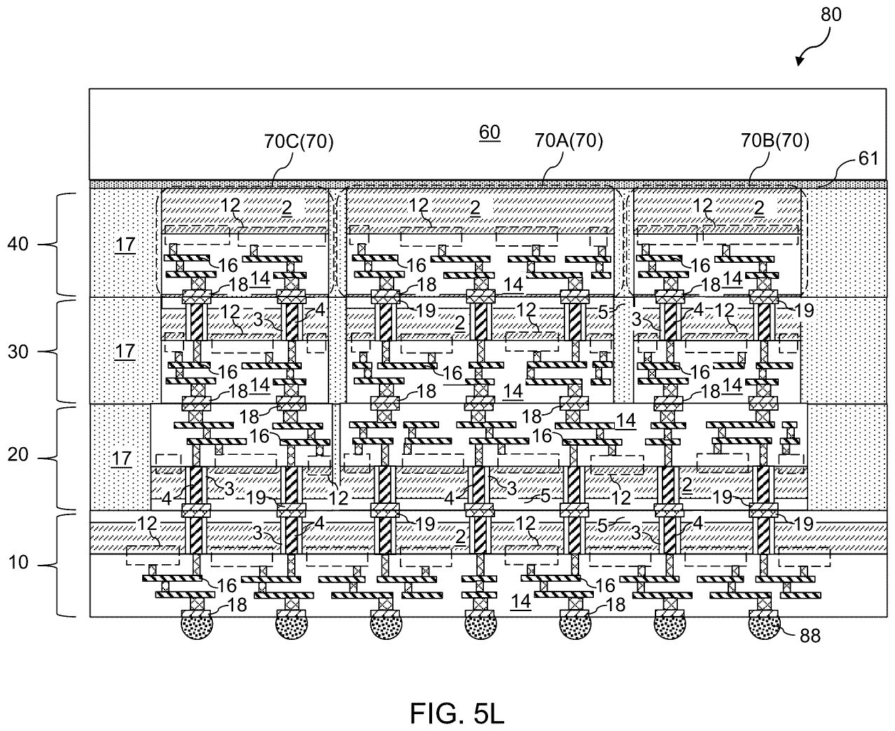

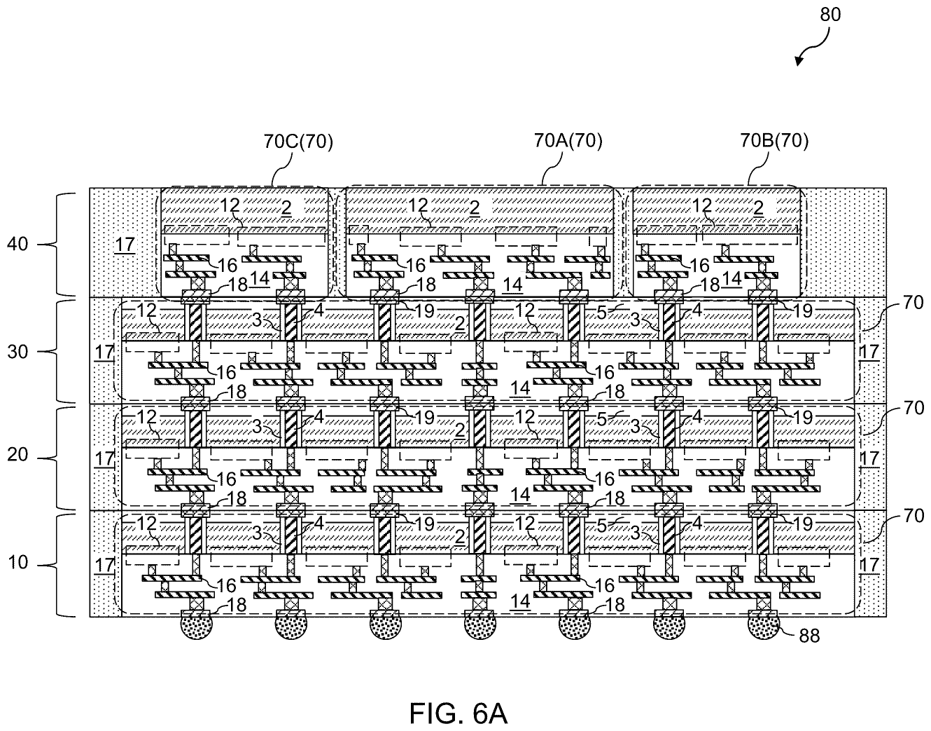

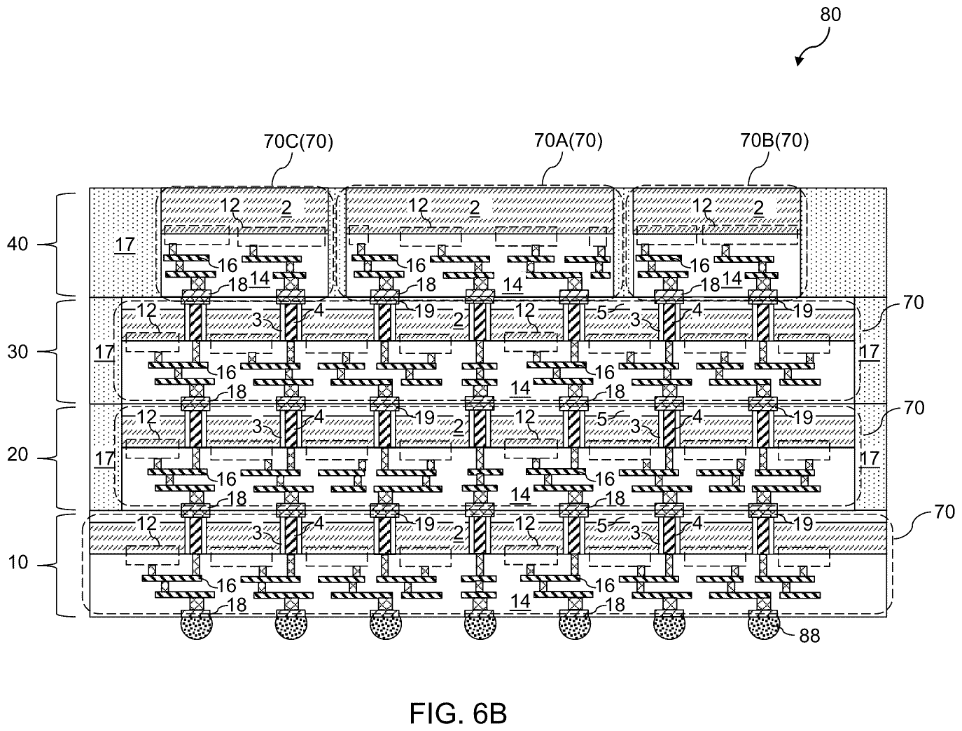

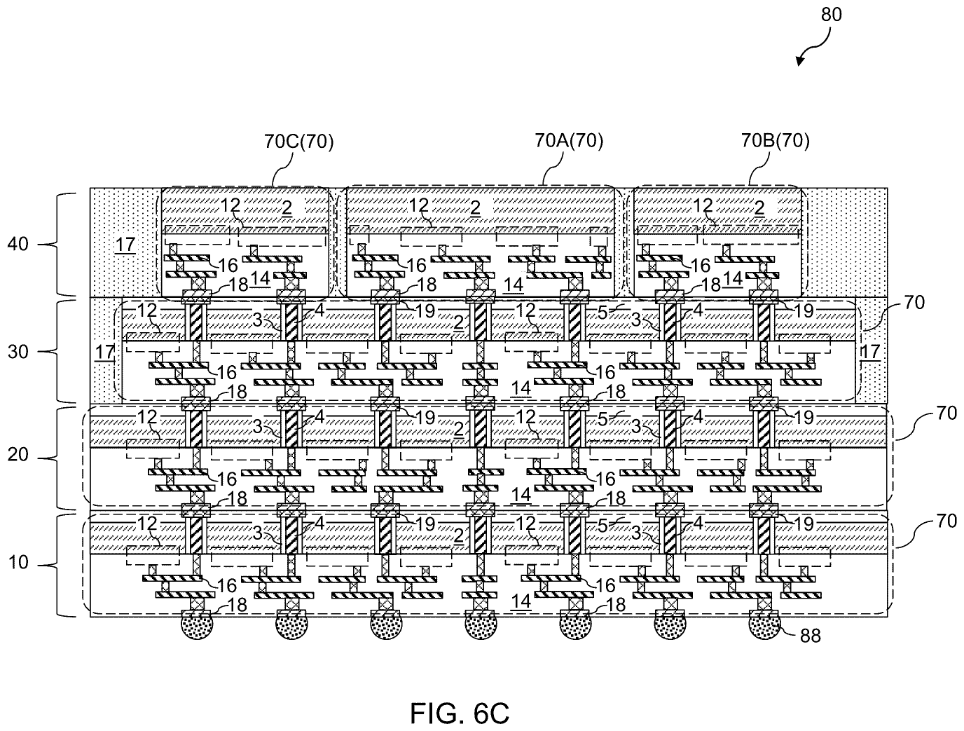

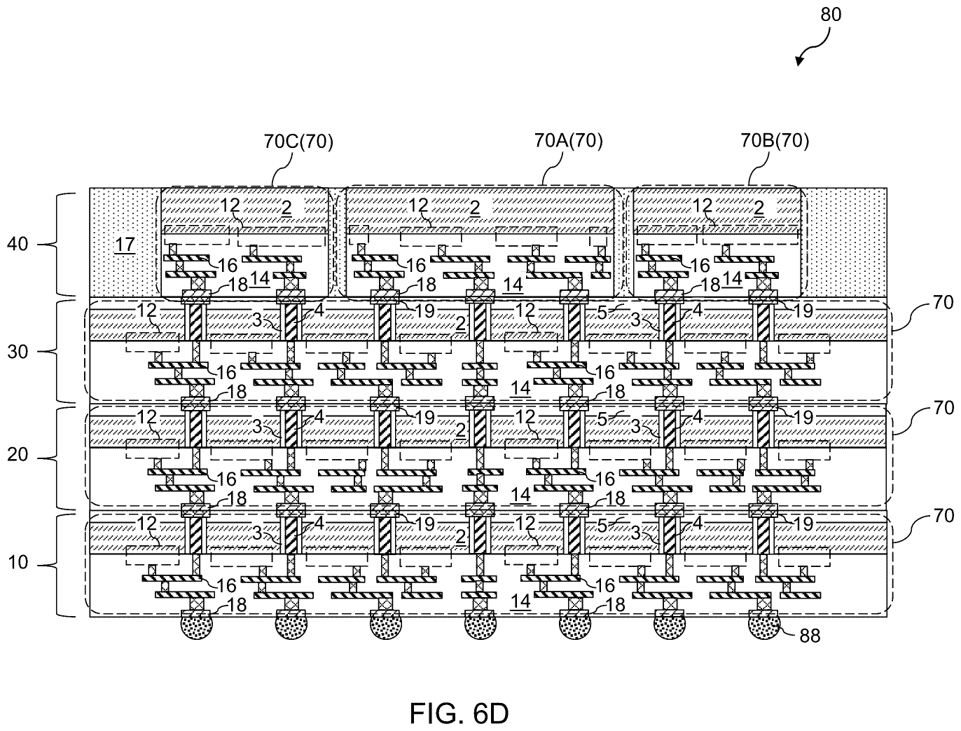

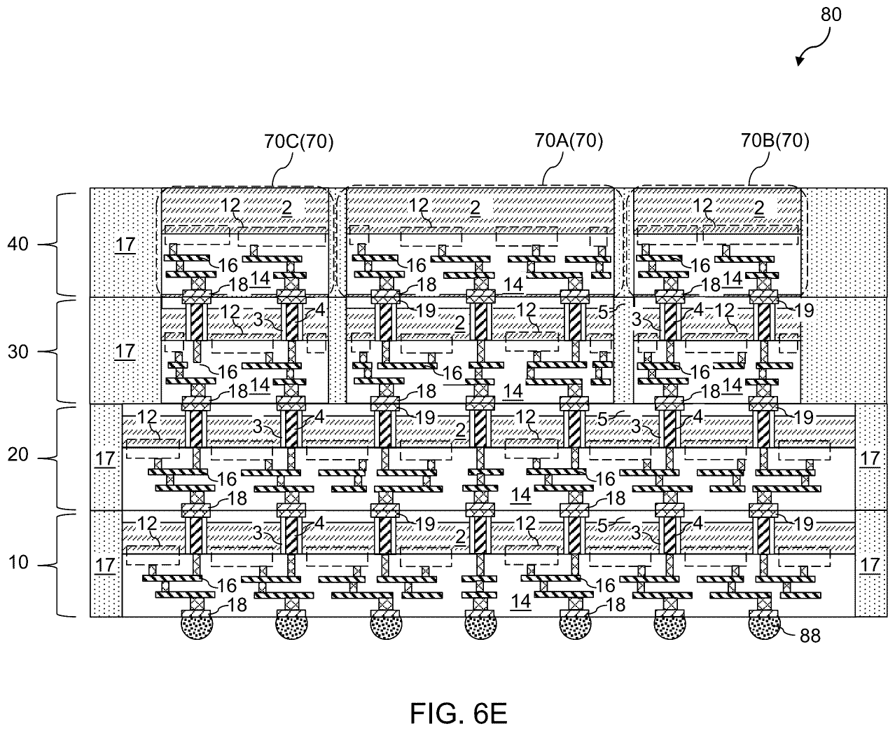

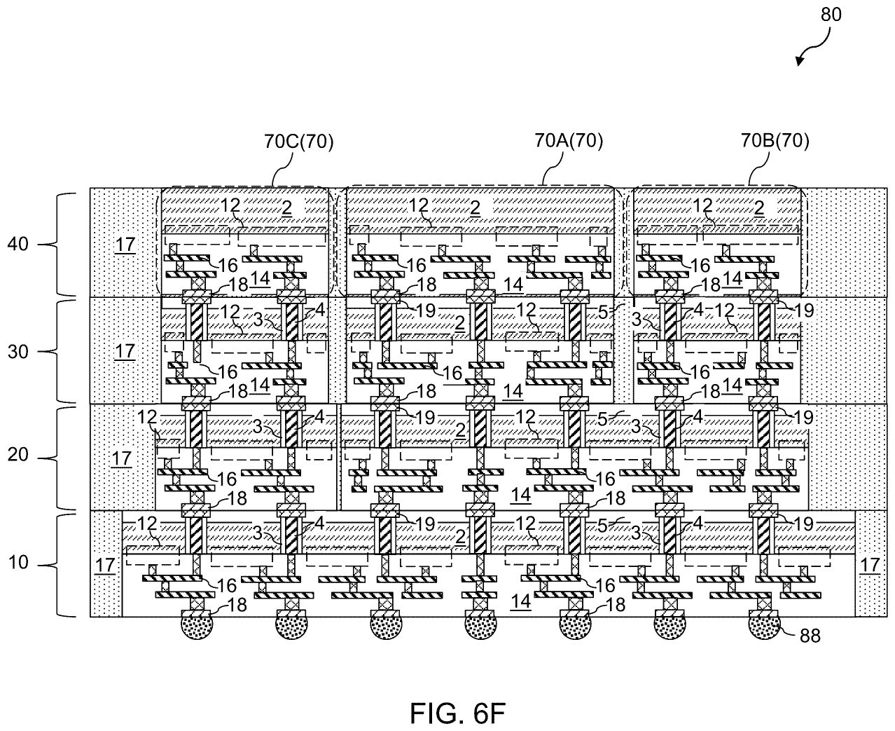

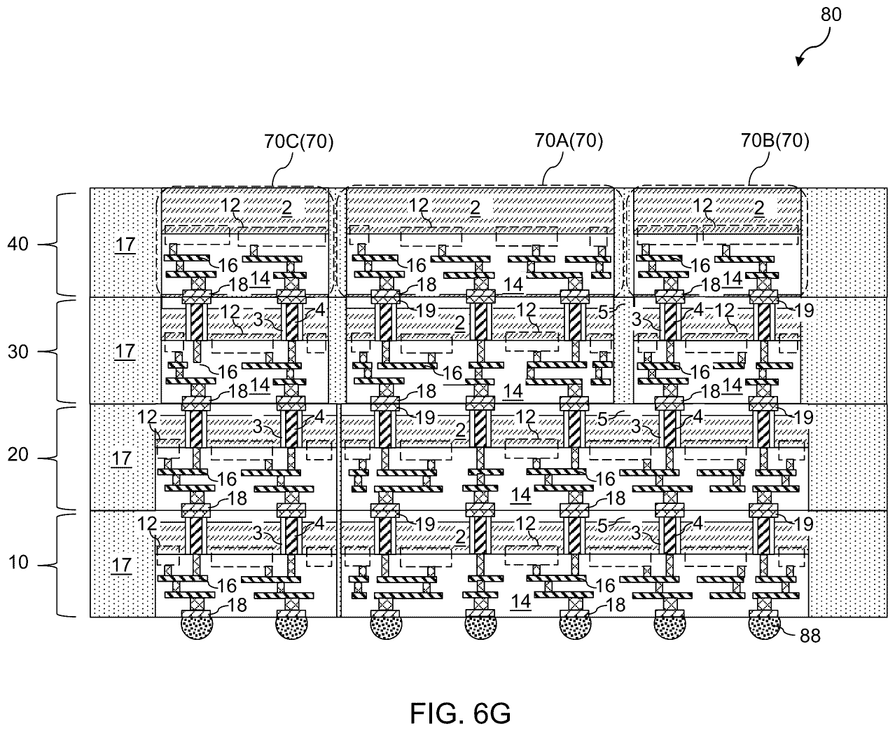

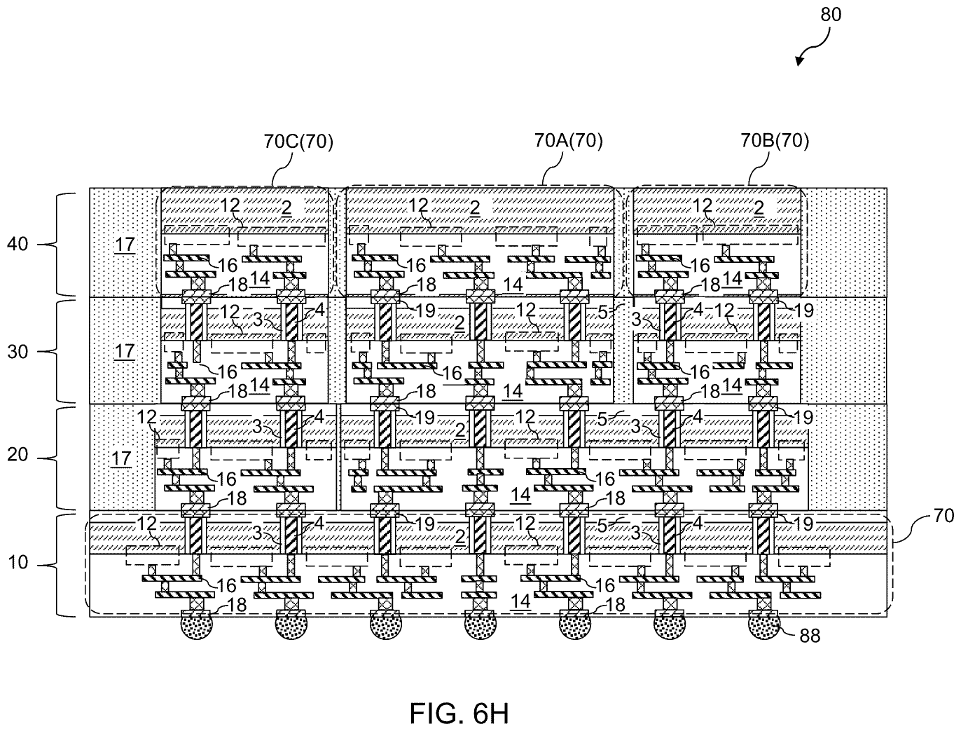

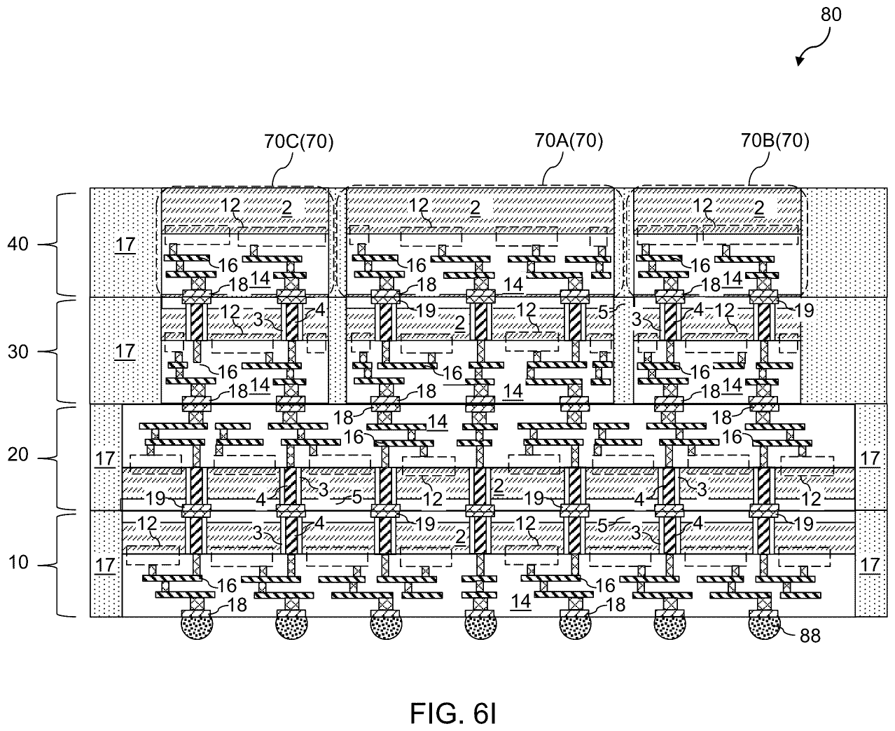

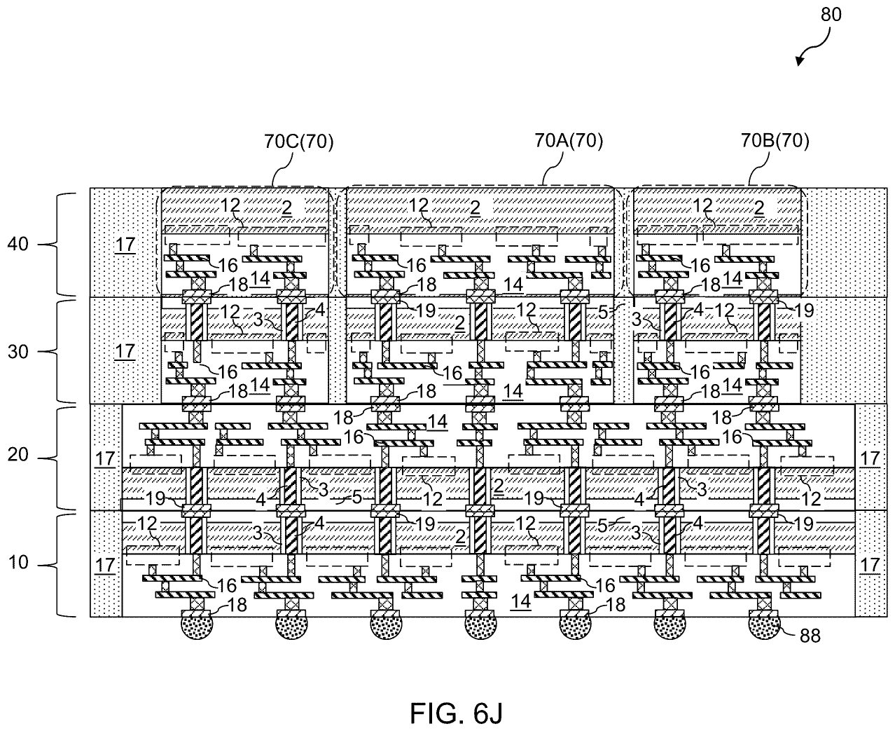

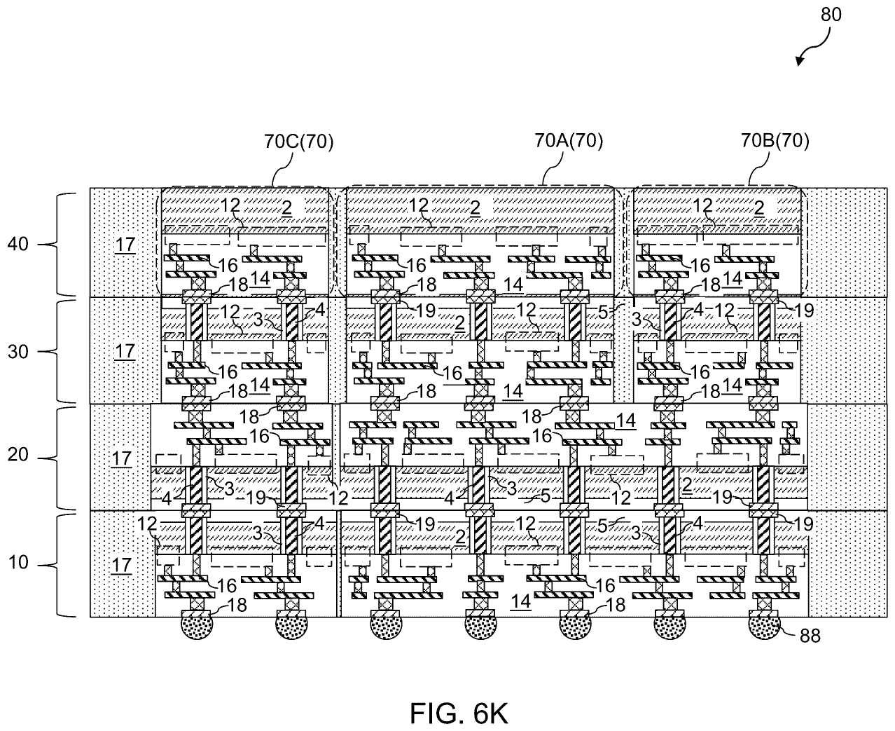

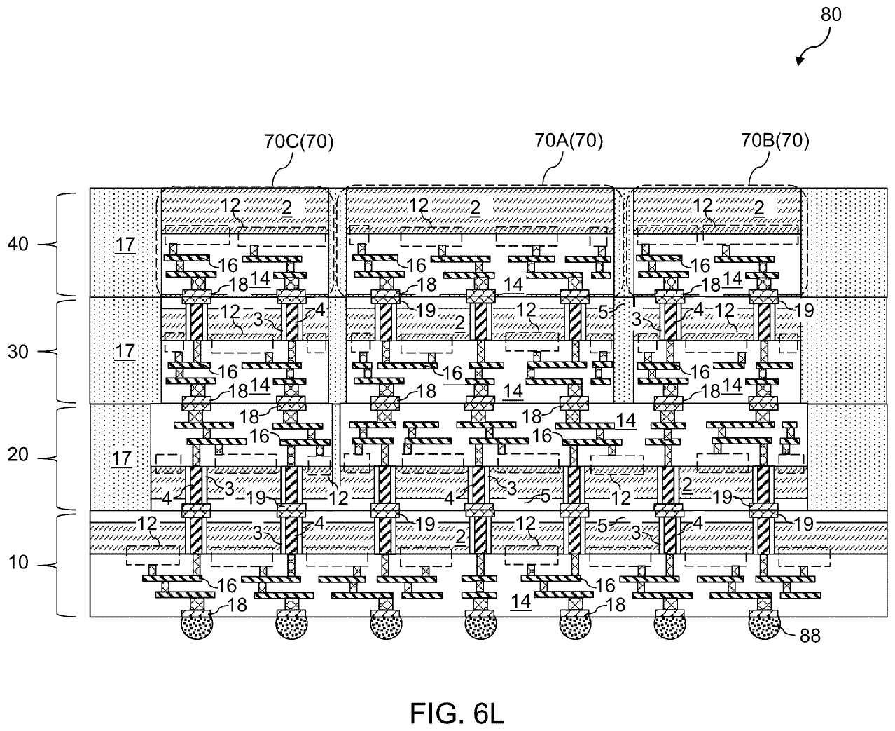

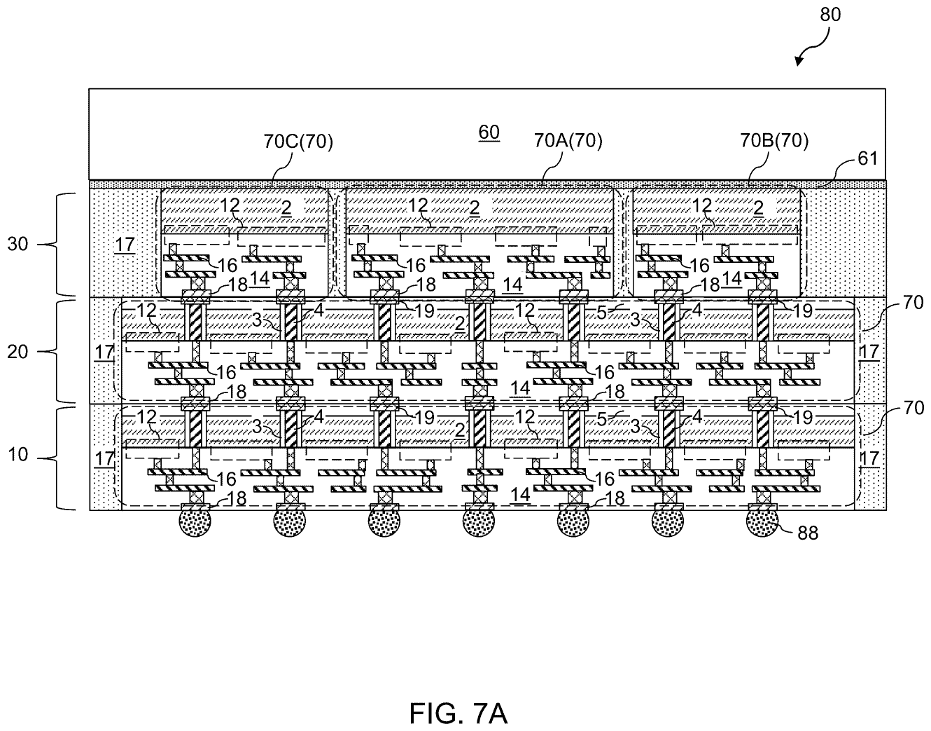

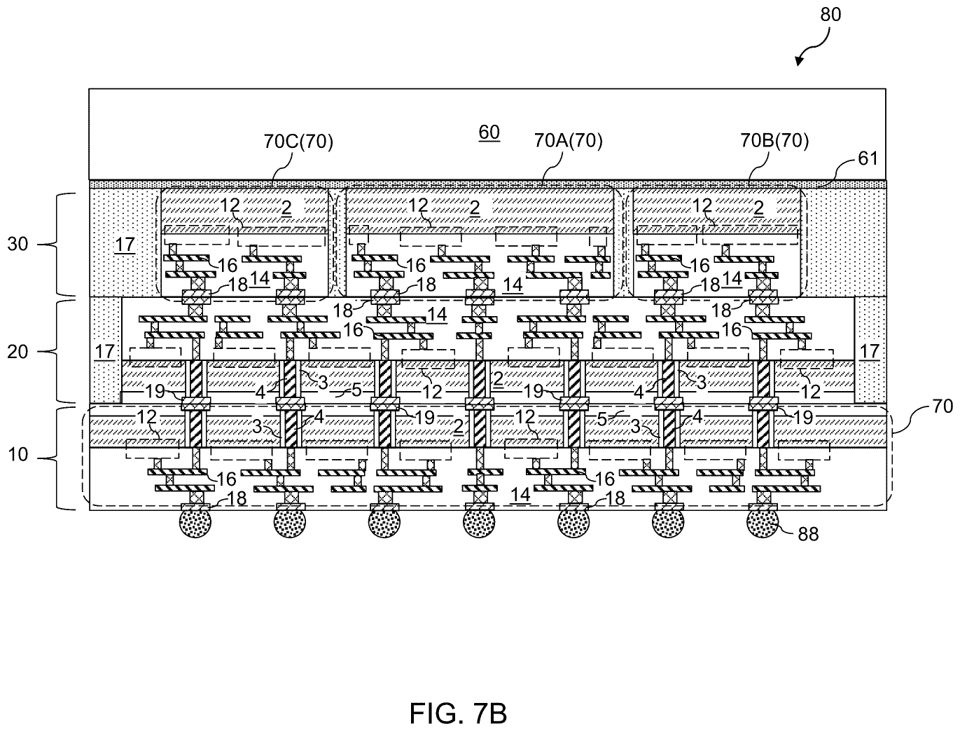

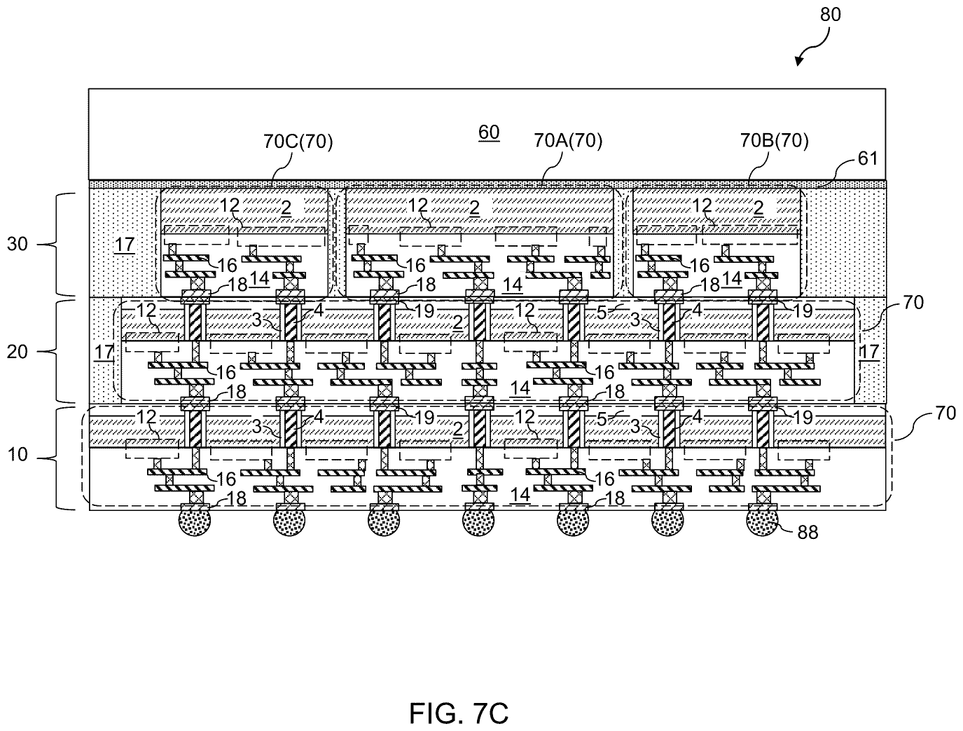

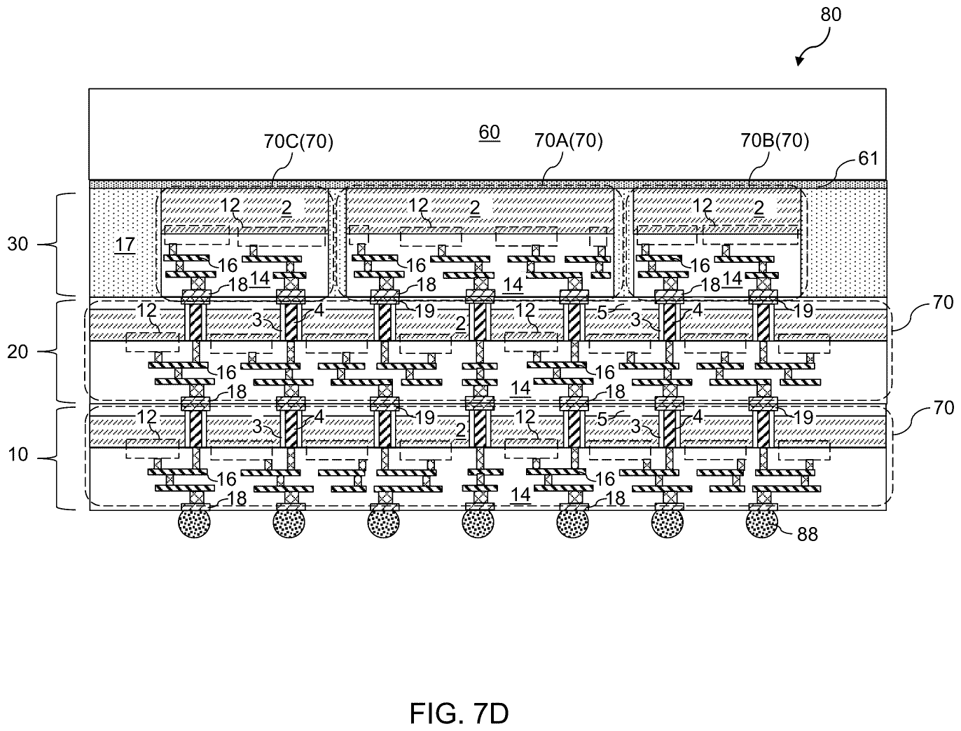

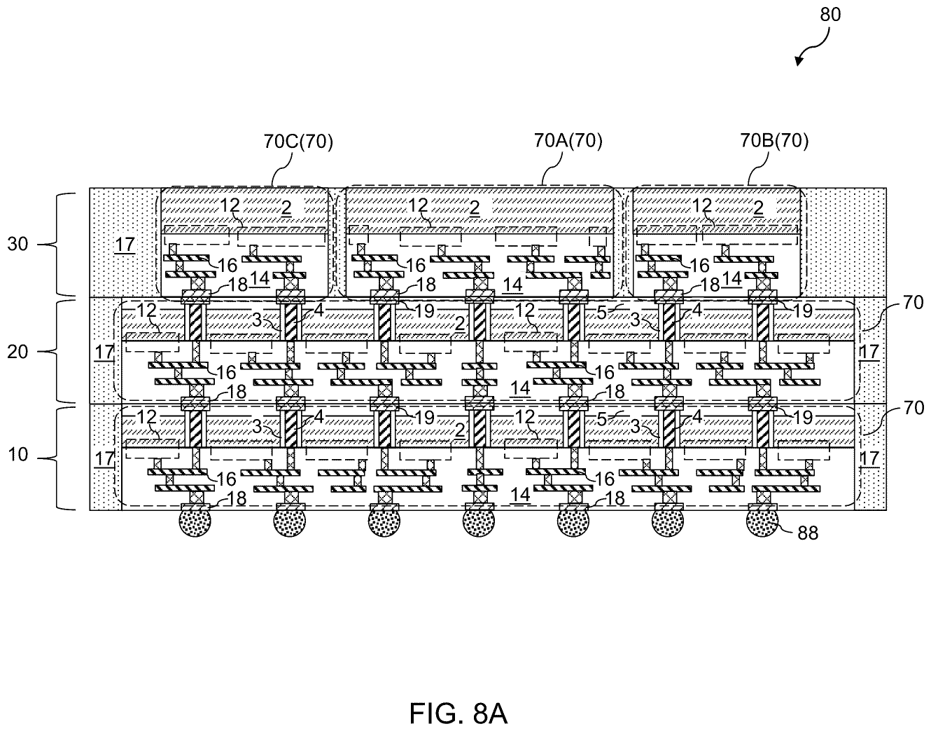

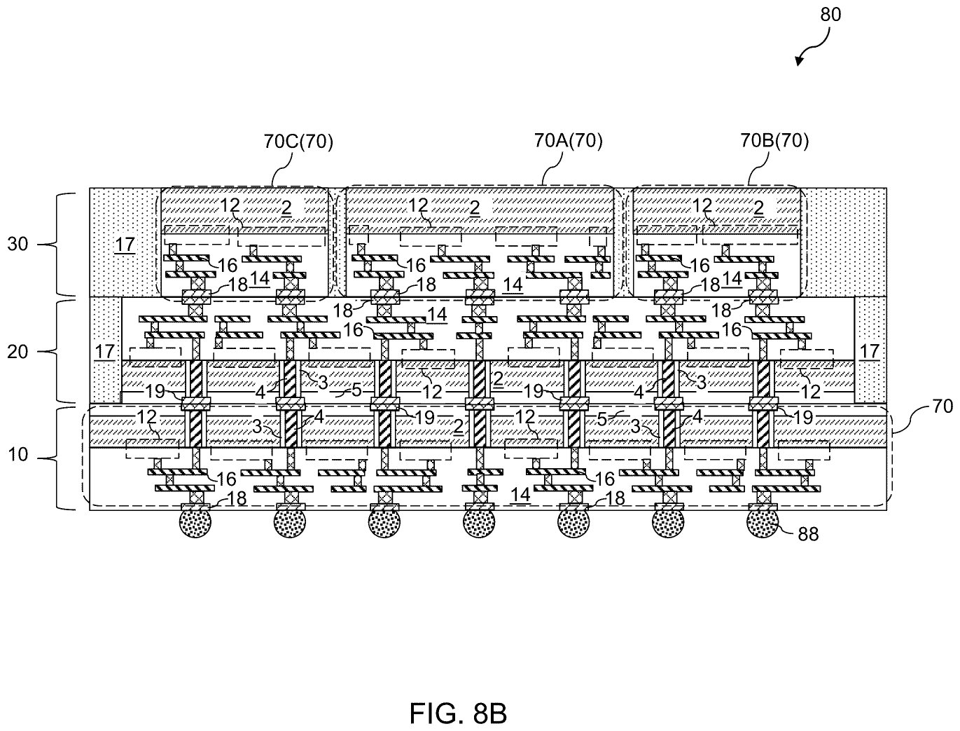

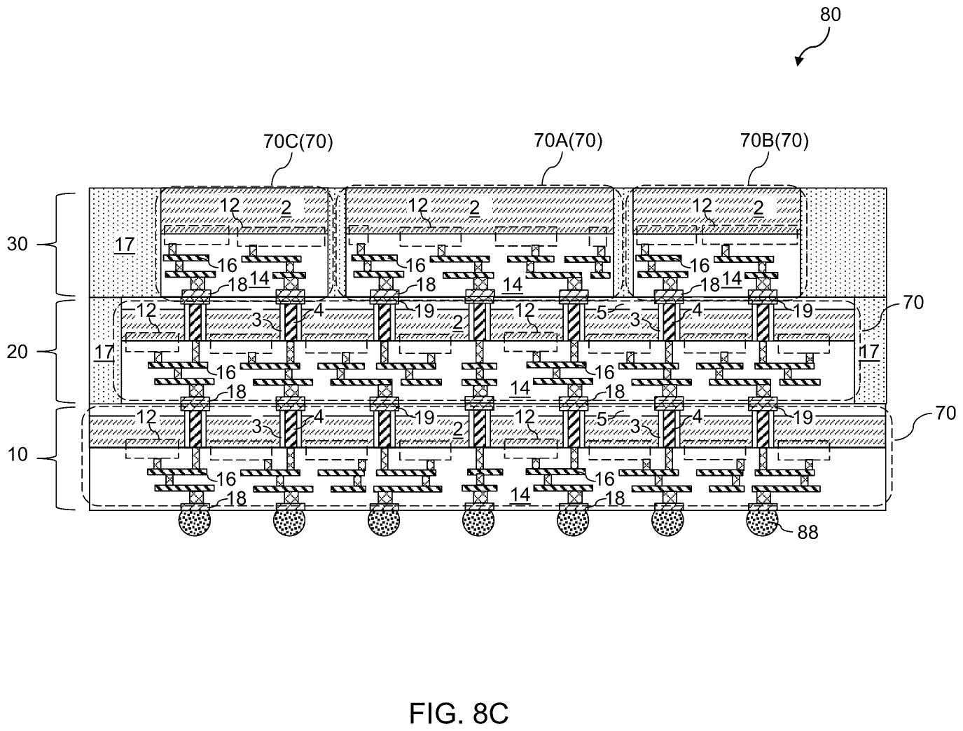

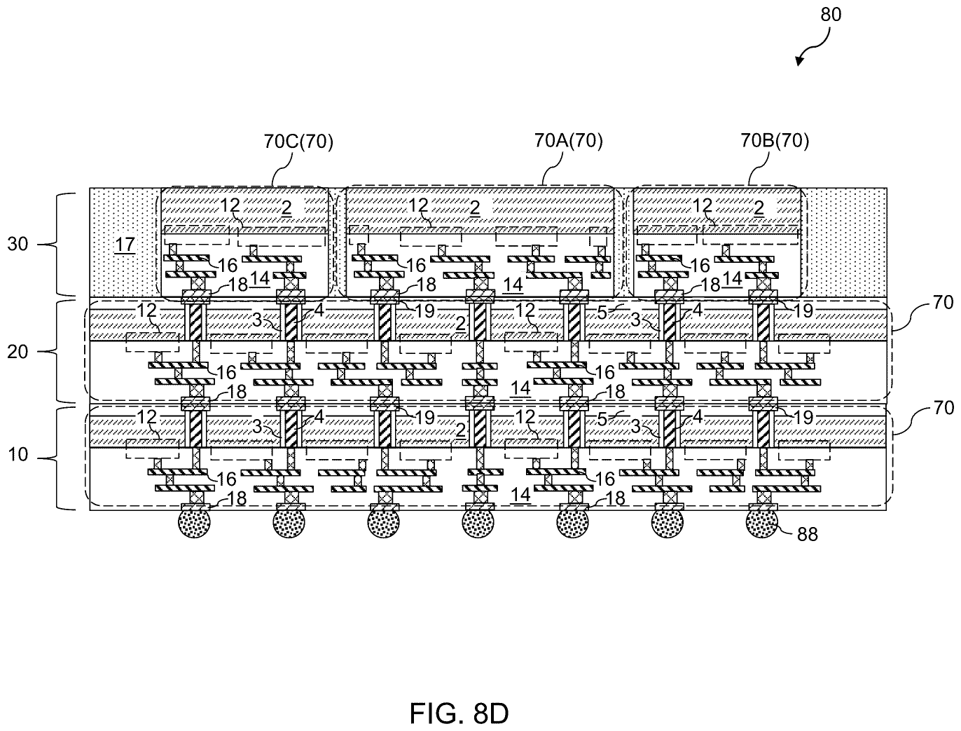

The composite package 80 of the present disclosure may be provided in various configurations depending on the configurations of each wafer (100, 200, 300, 400) and the total number of wafers (100, 200, 300, 400) in the bonded assembly that is diced. FIGS. 5A-5L are vertical cross-sectional view of various configurations of a first composite package 80 according to embodiments of the present disclosure. FIGS. 6A-6L are vertical cross-sectional view of various configurations of a second composite package 80 according to embodiments of the present disclosure. FIGS. 7A-7D are vertical cross-sectional view of various configurations of a third composite package 80 according to embodiments of the present disclosure. FIGS. 8A-8D are vertical cross-sectional view of various configurations of a fourth composite package 80 according to embodiments of the present disclosure.

Referring collectively to FIGS. 5A-5L, 6A-6L, 7A-7D, and 8A-8D, each diced portion of the first wafer 100 constitutes a first semiconductor package 10; each diced portion of the second wafer 200 constitutes a second semiconductor package 20; each diced potion of the third wafer 300 constitutes a third semiconductor package 30; and each diced portion of the fourth wafer 400 constitutes a fourth semiconductor package 40. Each first semiconductor package comprises at least one first semiconductor die 70; each second semiconductor package comprises at least one second semiconductor die 70; each third semiconductor package comprises at least one third semiconductor die 70; and each second semiconductor package comprises at least one fourth semiconductor die 70.

Each semiconductor package (10, 20, 30, 40) comprises at least one semiconductor die 70. Each semiconductor package (10, 20, 30, 40) may consist of a single semiconductor die 70, or may comprise a molding compound die frame 17 and at least one semiconductor die 70 (which may be a single semiconductor die 70 or a plurality of semiconductor dies 70) that is laterally surrounded by the molding compound die frame 17.

Each first semiconductor package 10 may, or may not comprise, a molding compound die frame 17; each second semiconductor package 20 may, or may not comprise, a molding compound die frame 17; each third semiconductor package 30 may, or may not comprise, a molding compound die frame 17; and each fourth semiconductor package 40 may, or may not comprise, a molding compound die frame 17. Each molding compound die frame 17 comprises a diced portion of a respective molding compound matrix. The sidewalls of the first semiconductor package 10, the second semiconductor package 20, the third semiconductor package 30, and the fourth semiconductor package 40 (if present) within a same composite package 80 are vertically coincident. As used herein, a first surface and a second surface are vertically coincident with each other if the second surface overlies or underlies the first surface and if there exists a vertical plane including the first surface and the second surface.

Referring to FIGS. 5A-5L, various configurations of a first composite package 80 according to embodiments of the present disclosure are illustrated. The first composite package 80 comprises a vertical stack of a first semiconductor package 10, a second semiconductor package 20, a third semiconductor package 30, a fourth semiconductor package 40, an adhesive layer 61, and a handle substrate 60.

The configuration illustrated in FIG. 5A corresponds to an embodiment in which each of the first wafer 100, the second wafer 200, the third wafer 300, and the fourth wafer 400 comprises a respective reconstituted wafer 118, which may be provided as described with reference to FIGS. 3A-3C, FIGS. 4A-4C, or the combination of the fifth processing steps S5 and the sixth processing step S6. As discussed above, each of the first wafer 100, the second wafer 200, the third wafer 300, and the fourth wafer 400 may be independently provided using any of the processing steps described with reference to FIGS. 3A-3C, the processing steps described with reference to FIGS. 4A-4C, or the processing steps described with reference to the combination of the fifth processing steps S5 and the sixth processing step S6.

The configuration illustrated in FIG. 5B corresponds to an embodiment in which the first wafer 100 comprises a semiconductor-based wafer described with reference to FIG. 2, and each of the second wafer 200, the third wafer 300, and the fourth wafer 400 comprises a respective reconstituted wafer 118, which may be provided as described with reference to FIGS. 3A-3C, FIGS. 4A-4C, or the combination of the fifth processing steps S5 and the sixth processing step S6.

The configuration illustrated in FIG. 5C corresponds to an embodiment in which each of the first wafer 100 and the second wafer 200 comprises a respective semiconductor-based wafer described with reference to FIG. 2, and each of the third wafer 300 and the fourth wafer 400 comprises a respective reconstituted wafer 118, which may be provided as described with reference to FIGS. 3A-3C, FIGS. 4A-4C, or the combination of the fifth processing steps S5 and the sixth processing step S6.

The configuration illustrated in FIG. 5D corresponds to an embodiment in which each of the first wafer 100, the second wafer 200, and the third wafer 300 comprises a respective semiconductor-based wafer described with reference to FIG. 2, and the fourth wafer 400 comprises a reconstituted wafer 118, which may be provided as described with reference to FIGS. 3A-3C, FIGS. 4A-4C, or the combination of the fifth processing steps S5 and the sixth processing step S6.

In the configurations illustrated in FIGS. 5A-5D, all semiconductor dies 70 face up or face down. In this embodiment, each metal-to-metal bonding occurs between a mating pair of a front metal bonding pad 18 and a backside metal bonding pad 19. In some configurations, all the semiconductor dies 70 face upward, and the front metal bonding pads 18 may be underlying metal bonding pads in an underlying wafer (100, 200, or 300) and the backside metal bonding pads 19 may be overlying metal bonding pads in an overlying wafer (200, 300, or 400). In some other configurations, all the semiconductor dies 70 face downward, and the front metal bonding pads 18 may be overlying metal bonding pads in an overlying wafer (200, 300, or 400) and the backside metal bonding pads 19 may be underlying metal bonding pads in an underlying wafer (100, 200, or 300). While FIGS. 5A-5D illustrate configurations in which all semiconductor dies 70 face downward, embodiments are expressly contemplated herein in which all the semiconductor dies 70 face upward.

Generally, each of the semiconductor packages (10, 20, 30, 40) in the composite package 80 may be derived from a respective semiconductor-based wafer such as a semiconductor-based wafer illustrated in FIG. 2, from a respective reconstituted wafer 118 including a single semiconductor die 70 per unit area UA such as the reconstituted wafer 118 illustrated in FIG. 3C, or from a respective reconstituted wafer 118 including a plurality of semiconductor dies per unit area UA such as the reconstituted wafer illustrated in FIG. 4C or at the processing steps S5 and S6 in FIG. 1.

FIGS. 5E-FIG. 5H illustrate additional configurations in which at least one semiconductor package (10, 20, 30, 40) in the composite packages 80 illustrated in FIGS. 5A-5D is replaced with a respective semiconductor package (10, 20, 30, 40) derived from a different type of wafer (100, 200, 300, 400).

For example, the configuration illustrated in FIG. 5E may be derived from the configuration illustrated in FIG. 5A by using a third semiconductor package 30 including a plurality of semiconductor dies 70 formed within a molding compound die frame 17. The configuration illustrated in FIG. 5F may be derived from the configuration illustrated in FIG. 5E by using a second semiconductor package 20 including a plurality of semiconductor dies 70 formed within a molding compound die frame 17. The configuration illustrated in FIG. 5G may be derived from the configuration illustrated in FIG. 5F by using a first semiconductor package 10 including a plurality of semiconductor dies 70 formed within a molding compound die frame 17. The configuration illustrated in FIG. 5H may be derived from the configuration illustrated in FIG. 5G by using a first semiconductor package 10 consisting of a single semiconductor die 70 that is derived from a first wafer 100 using a semiconductor-based wafer.

Referring to FIGS. 5I-5L, configurations are illustrated in which a first subset of the semiconductor packages (10, 20, 30, 40) face upward and a second subset (which is the complementary subset) of the semiconductor packages (10, 20, 30, 40) face downward. In this embodiment, backside metal bonding pads 19 of at least one overlying semiconductor die 70 in an overlying semiconductor package (20, 30 or 40) may be bonded to backside metal bonding pads 19 of at least one underlying semiconductor die 70 in an underlying semiconductor package (10, 20, or 30). Alternatively or additionally, front metal bonding pads 18 of at least one overlying semiconductor die 70 in an overlying semiconductor package (20, 30 or 40) may be bonded to front metal bonding pads 18 of at least one underlying semiconductor die 70 in an underlying semiconductor package (10, 20, or 30).

For example, the configuration illustrated in FIG. 5I may be derived from the configuration illustrated in FIG. 5E by flipping the second semiconductor package 20 upside down; the configuration illustrated in FIG. 5J may be derived from the configuration illustrated in FIG. 5F by flipping the second semiconductor package 20 upside down; the configuration illustrated in FIG. 5K may be derived from the configuration illustrated in FIG. 5G by flipping the second semiconductor package 20 upside down; and the configuration illustrated in FIG. 5L may be derived from the configuration illustrated in FIG. 5H by flipping the second semiconductor package 20 upside down. Embodiments are expressly contemplated herein in which an alternative semiconductor package (10, 30, 40) and/or at least one additional semiconductor package (10, 30, 40) is/are flipped upside down.

FIGS. 6A-6L are vertical cross-sectional view of various configurations of a second composite package 80 according to embodiments of the present disclosure. Generally, the second composite packages 80 illustrated in FIGS. 6A-6L may be derived from the first composite packages 80 illustrated in FIGS. 5A-5L by removing the third semiconductor package 30 within each composite package. In such embodiments, the fourth processing step S7 may be omitted and a second carrier wafer 602 may not be used during the processing sequences described with reference to FIG. 1. Alternatively, the second carrier wafer 602 may be detached prior to the dicing step, i.e., the ninth processing step S9. In this embodiment, the composite package 80 does not include a handle substrate 60 or the adhesive layer 61. The configurations illustrated in FIGS. 6A-6L may be derived from the configurations illustrated in FIG. 5A-5L, respectively, by omitting formation of a handle substrate 60 and an adhesive layer 61.

As discussed above, the composite packages 80 of the present disclosure includes a vertical stack of three or more semiconductor packages (10, 20, 30, 40). The total number of semiconductor packages (10, 20, 30, 40) in the vertical stack may be 3, 4, 5, or 6 or more.

Referring to FIGS. 7A-7D, various exemplary configurations for a third composite package 80 according to embodiments of the present disclosure are illustrated, which may be derived from any of the first composite packages 80 illustrated in FIGS. 5A-5L by reducing the total number of semiconductor packages (10, 20, 30) within the vertical stack to 3.

Referring to FIGS. 8A-8D, various exemplary configurations for a fourth composite package 80 according to embodiments of the present disclosure are illustrated, which may be derived from any of the second composite packages 80 illustrated in FIGS. 6A-6L by reducing the total number of semiconductor packages (10, 20, 30) within the vertical stack to 3.

Referring collectively to FIGS. 1, 2, 3A-3C, 4A-4C, 5A-5L, 6A-6L, 7A-7D, and 8A-8D and according to various embodiments of the present disclosure, a composite package 80 comprising a vertical stack of at least a first semiconductor package 10, a second semiconductor package 20, and a third semiconductor package 30 is provided. The first semiconductor package 10 comprises at least one first semiconductor die 70 comprising first metal bonding pads (18, 19); the second semiconductor package 20 comprises at least one second semiconductor die 70 comprising second metal bonding pads (18, 19); the third semiconductor package 30 comprises at least one third semiconductor die 70 comprising third metal bonding pads (18, 19); each vertically neighboring pair of semiconductor packages within the vertical stack is bonded to each other by metal-to-metal bonding between mating pairs of metal bonding pads (18, 19); and vertical sidewalls of at least three semiconductor packages (10, 20, 30, optionally 40) comprising the first semiconductor package 10, the second semiconductor package 20, and the third semiconductor package 30 are vertically coincident with one another.

In one embodiment, a first one of the at least three semiconductor packages (10, 20, 30, optionally 40) comprises a molding compound die frame 17 laterally surrounding one of the at least one first semiconductor die 70, the at least one second semiconductor die 70, and the at least one third semiconductor die 70. In one embodiment, a second one of the at least three semiconductor packages (10, 20, 30, optionally 40) comprises an additional molding compound die frame 17 laterally surrounding another one of the at least one first semiconductor die 70, the at least one second semiconductor die 70, and the at least one third semiconductor die 70.

In one embodiment, the at least one first semiconductor die 70 consist of a single semiconductor die 70 having sidewalls that are vertically coincident with outer sidewalls of the molding compound die frame 17. In one embodiment, the at least one third semiconductor die 70 comprises a plurality of third semiconductor dies 70 that are laterally spaced apart from one another by, and are laterally surrounded by, a molding compound die frame 17.

According to another aspect of the present disclosure, a composite package 80 comprising a vertical stack of at least a first semiconductor package 10, a second semiconductor package 20, and a third semiconductor package 30 is provided. The first semiconductor package 10 comprises at least one first semiconductor die 70 comprising first metal bonding pads (18, 19); the second semiconductor package 20 comprises at least one second semiconductor die 70 comprising second metal bonding pads (18, 19); the third semiconductor package 30 comprises at least one third semiconductor die 70 comprising third metal bonding pads (18, 19); each vertically neighboring pair of semiconductor packages within the vertical stack is bonded to each other by metal-to-metal bonding between mating pairs of metal bonding pads (18, 19); and each of the at least one second semiconductor die 70 comprises a respective array of through-substrate via (TSV) structures 4 contacting a subset of the second metal bonding pads (18, 19).

In one embodiment, the at least one first semiconductor die 70 comprises first top metal bonding pads (18, 19); the at least one second semiconductor die 70 comprises second bottom metal bonding pads (18, 19) that are bonded to the first top metal bonding pads (18, 19) and further comprises second top metal bonding pads (18, 19); and the at least one third semiconductor die 70 comprises third bottom metal bonding pads (18, 19) that are bonded to the second top metal bonding pads (18, 19). In one embodiment, the subset of the second metal bonding pads (18, 19) comprises the second top metal bonding pads (18, 19). In one embodiment, the subset of the second metal bonding pads (18, 19) comprises the second bottom metal bonding pads (18, 19).

In one embodiment, a first one of the at least three semiconductor packages (10, 20, 30, optionally 40) comprises a molding compound die frame 17 laterally surrounding one of the at least one first semiconductor die 70, the at least one second semiconductor die 70, and the at least one third semiconductor die 70. In one embodiment, a second one of the at least three semiconductor packages (10, 20, 30, optionally 40) comprises an additional molding compound die frame 17 laterally surrounding another one of the at least one first semiconductor die 70, the at least one second semiconductor die 70, and the at least one third semiconductor die 70.

In one embodiment, sidewalls of the second semiconductor package 20 are vertically coincident with sidewalls of the first semiconductor package 10 and with sidewalls of the third semiconductor package 30. In one embodiment, the at least one third semiconductor die 70 comprises a plurality of third semiconductor dies 70. In one embodiment, the at least one second semiconductor die 70 comprises a plurality of second semiconductor dies 70. In one embodiment, the composite package 80 comprises an array of solder material portions 88 attached to the first semiconductor package 10.

According to yet another aspect of the present disclosure, a composite package 80 comprising a vertical stack of at least a first semiconductor package 10, a second semiconductor package 20, and a third semiconductor package 30 is provided. The first semiconductor package 10 comprises at least one first semiconductor die 70 comprising first metal bonding pads (18, 19); the second semiconductor package 20 comprises at least one second semiconductor die 70 comprising second metal bonding pads (18, 19); the third semiconductor package 30 comprises at least one third semiconductor die 70 comprising third metal bonding pads (18, 19); each vertically neighboring pair of semiconductor packages within the vertical stack is bonded to each other by metal-to-metal bonding between mating pairs of metal bonding pads (18, 19); sidewalls of the second semiconductor package 20 are vertically coincident with sidewalls of the first semiconductor package 10 and with sidewalls of the second semiconductor package 20; and one or more of the at least one first semiconductor die 70, the at least one second semiconductor die 70, and the at least one third semiconductor die 70 comprises a respective sidewall that is laterally offset from the sidewalls of the second semiconductor package 20.

In one embodiment, a first one of the at least three semiconductor packages (10, 20, 30, optionally 40) comprises a molding compound die frame 17 laterally surrounding one of the at least one first semiconductor die 70, the at least one second semiconductor die 70, and the at least one third semiconductor die 70. In one embodiment, a second one of the at least three semiconductor packages (10, 20, 30, optionally 40) comprises an additional molding compound die frame 17 laterally surrounding another one of the at least one first semiconductor die 70, the at least one second semiconductor die 70, and the at least one third semiconductor die 70. In one embodiment, a horizontal surface of the molding compound die frame 17 is in contact with a horizontal surface of the additional molding compound die frame 17.

In one embodiment, at least one of the semiconductor packages (10, 20, 30) comprises at least one additional semiconductor die 70. In one embodiment, the at least one third semiconductor die 70 comprises a plurality of third semiconductor dies 70.

FIG. 9 is a first flowchart illustrating steps for forming a semiconductor structure according to an embodiment of the present disclosure.

Referring to step 910 of FIG. 9 and the first auxiliary processing step A1 of FIG. 1 and FIGS. 2, 3A-3C, and 4A-4C, a first wafer 100 including a two-dimensional array of first semiconductor dies 70 including arrays of first top metal bonding pads (18, 19) and arrays of first bottom metal bonding pads (18, 19) may be provided.

Referring to step 920 of FIG. 9 and the second auxiliary processing step A2 of FIG. 1 and FIGS. 2, 3A-3C, and 4A-4C, a second wafer 200 including a two-dimensional array of second semiconductor dies 70 including arrays of second top metal bonding pads (18, 19) and arrays of second bottom metal bonding pads (18, 19) may be provided.

Referring to step 930 of FIG. 9 and the third processing step S3 of FIG. 1 and FIGS. 2, 3A-3C, 4A-4C, 5A-5L, 6A-6L, 7A-7D, and 8A-8D, the second wafer 200 may be bonded to the first wafer 100 by performing a first metal-to-metal bonding process in which the arrays of first top metal bonding pads (18, 19) are bonded to the arrays of second bottom metal bonding pads (18, 19) through first intermetallic diffusion.

Referring to step 940 of FIG. 9 and the third auxiliary processing step A3 of FIG. 1 and FIGS. 2, 3A-3C, 4A-4C. 5A-5L, 6A-6L, 7A-7D, and 8A-8D, a third wafer 300 including a two-dimensional array of third semiconductor dies 70 including arrays of third bottom metal bonding pads (18, 19) may be provided.

Referring to step 950 of FIG. 9 and the fourth processing step S4 of FIG. 1 and FIGS. 2, 3A-3C, 4A-4C. 5A-5L, 6A-6L, 7A-7D, and 8A-8D, the third wafer 300 may be bonded to the second wafer 200 by performing a second metal-to-metal bonding process in which the arrays of second top metal bonding pads (18, 19) are bonded to the arrays of third bottom metal bonding pads (18, 19) through second intermetallic diffusion.

In one embodiment, the third wafer 300 may comprise a reconstituted wafer in which the third semiconductor dies 70 are laterally surrounded by a molding compound matrix 17. In one embodiment, the second wafer 200 may comprise an additional reconstituted wafer in which the second semiconductor dies 70 are laterally surrounded by an additional molding compound matrix 17. In one embodiment, the first semiconductor dies 70 may be interconnected to one another, and each of the first semiconductor dies 70 may comprise a respective portion of a semiconductor substrate 2 that continuously extends over an entire area of the first wafer 100. In one embodiment, the first wafer 100 may comprise another additional reconstituted wafer in which the first semiconductor dies 70 are laterally surrounded by another additional molding compound matrix 17. In one embodiment, the third semiconductor dies comprises first-type semiconductor dies and second-type semiconductor dies; and the two-dimensional array of third semiconductor dies comprises a two-dimensional periodic array of a repletion unit that includes a combination of a first-type semiconductor die and a second-type semiconductor die that is different from the first-type semiconductor die. In one embodiment, the method may further include dicing a bonded assembly comprising at least the first wafer 100, the second wafer 200, and the third wafer 300 into a plurality of composite packages each comprising an assembly of a respective one of the first semiconductor dies, a respective one of the second semiconductor dies, and a respective one of the third semiconductor dies. In one embodiment, each of the composite packages may comprise a respective additional one of the third semiconductor dies.

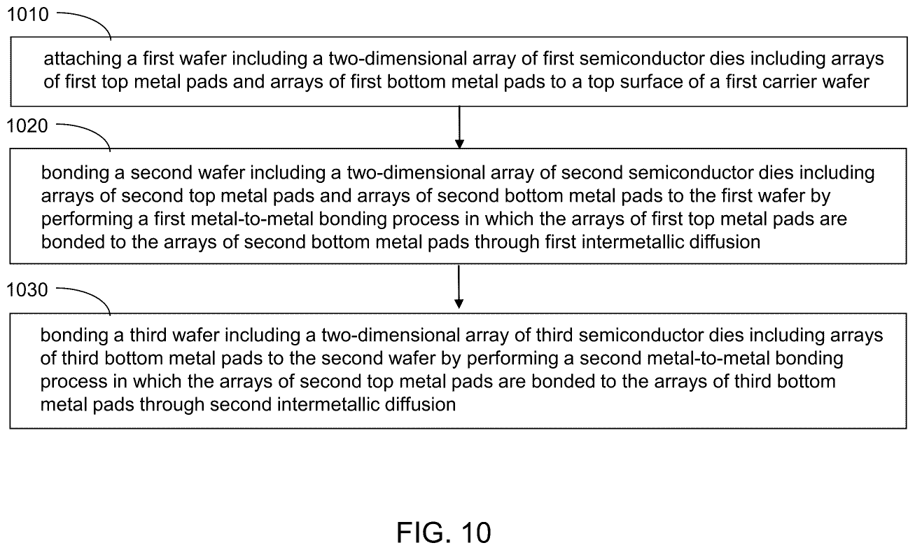

FIG. 10 is a second flowchart illustrating steps for forming a semiconductor structure according to an embodiment of the present disclosure.

Referring to step 1010 of FIG. 10 and the second processing step S2 of FIG. 1 and FIGS. 2, 3A-3C, and 4A-4C, a first wafer 100 including a two-dimensional array of first semiconductor dies 70 including arrays of first top metal bonding pads (18, 19) and arrays of first bottom metal bonding pads (18, 19) may be attached to a top surface of a first carrier wafer 601.

Referring to step 1020 of FIG. 10 and the third processing step S3 of FIG. 1 and FIGS. 2, 3A-3C, 4A-4C. 5A-5L, 6A-6L, 7A-7D, and 8A-8D, a second wafer 200 including a two-dimensional array of second semiconductor dies 70 including arrays of second top metal bonding pads (18, 19) and arrays of second bottom metal bonding pads (18, 19) may be attached to the first wafer 100 by performing a first metal-to-metal bonding process in which the arrays of first top metal bonding pads (18, 19) are bonded to the arrays of second bottom metal bonding pads (18, 19) through first intermetallic diffusion.

Referring to step 1030 of FIG. 10 and the fourth processing step S4 of FIG. 1 and FIGS. 2, 3A-3C, 4A-4C. 5A-5L, 6A-6L, 7A-7D, and 8A-8D, a third wafer 300 including a two-dimensional array of third semiconductor dies 70 including arrays of third bottom metal bonding pads (18, 19) may be attached to the second wafer 200 by performing a second metal-to-metal bonding process in which the arrays of second top metal bonding pads (18, 19) are bonded to the arrays of third bottom metal bonding pads (18, 19) through second intermetallic diffusion.

In one embodiment, the method may also include the steps of attaching a second carrier wafer 200 to a top surface of a bonded assembly comprising the first carrier wafer 601, the first wafer 100, the second wafer 200, and the third wafer 300; and detaching the first carrier wafer 601 from the first wafer 100 after attaching the second carrier wafer 602 to the bonded assembly. In one embodiment, the method may also include the steps of attaching arrays of solder material portions to the arrays of first bottom metal bonding pads 19; and dicing the bonded assembly into a plurality of composite packages 80 each comprising a vertical stack of a respective one of the first semiconductor dies, a respective one of a second semiconductor dies, and a respective one of the third semiconductor dies. In one embodiment, one of the first wafer 100, the second wafer 200, and the third wafer 300 may comprise a reconstituted wafer in which a molding compound matrix 17 laterally surrounds the first semiconductor dies, the second semiconductor dies, or the third semiconductor dies. In one embodiment, another of the first wafer 100, the second wafer 200, and the third wafer 300 may comprise an additional reconstituted wafer comprising an additional molding compound matrix 17. In one embodiment, the third semiconductor dies may comprise first-type semiconductor dies and second-type semiconductor dies; and the third wafer 300 may comprise a two-dimensional periodic array of a repletion unit that includes a combination of a first-type semiconductor die and a second-type semiconductor die that is different from the first-type semiconductor die. In one embodiment, the two-dimensional array of third semiconductor dies including arrays of third top metal bonding pads; and the method may also include the step of attaching a fourth wafer 400 comprising a two-dimensional array of fourth semiconductor dies including arrays of fourth bottom metal bonding pads to the third wafer 300 by performing a third metal-to-metal bonding process in which the arrays of third top metal bonding pads are bonded to the arrays of fourth bottom metal bonding pads through third intermetallic diffusion.

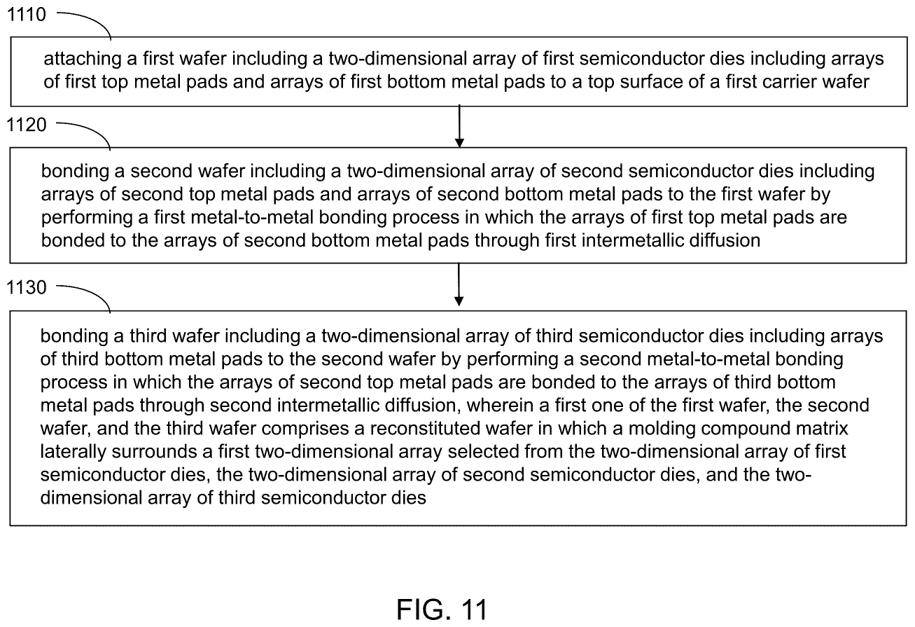

FIG. 11 is a third flowchart illustrating steps for forming a semiconductor structure according to an embodiment of the present disclosure.

Referring to step 1110 of FIG. 11 and the second processing step S2 of FIG. 1 and FIGS. 2, 3A-3C, and 4A-4C, a first wafer 100 including a two-dimensional array of first semiconductor dies 70 including arrays of first top metal bonding pads (18, 19) and arrays of first bottom metal bonding pads (18, 19) may be attached to a top surface of a first carrier wafer 601.

Referring to step 1120 of FIG. 11 and the third processing step S3 of FIG. 1 and FIGS. 2, 3A-3C, 4A-4C. 5A-5L, 6A-6L, 7A-7D, and 8A-8D, a second wafer 200 including a two-dimensional array of second semiconductor dies 70 including arrays of second top metal bonding pads (18, 19) and arrays of second bottom metal bonding pads (18, 19) may be attached to the first wafer 100 by performing a first metal-to-metal bonding process in which the arrays of first top metal bonding pads (18, 19) are bonded to the arrays of second bottom metal bonding pads (18, 19) through first intermetallic diffusion.

Referring to step 1130 of FIG. 11 and the fourth processing step S4 of FIG. 1 and FIGS. 2, 3A-3C, 4A-4C. 5A-5L, 6A-6L, 7A-7D, and 8A-8D, a third wafer 300 including a two-dimensional array of third semiconductor dies 70 including arrays of third bottom metal bonding pads (18, 19) to the second wafer 200 by performing a second metal-to-metal bonding process in which the arrays of second top metal bonding pads (18, 19) are bonded to the arrays of third bottom metal bonding pads (18, 19) through second intermetallic diffusion. A first one of the first wafer 100, the second wafer 200, and the third wafer 300 comprises a reconstituted wafer in which a molding compound matrix 17M laterally surrounds a first two-dimensional array selected from the two-dimensional array of first semiconductor dies 70, the two-dimensional array of second semiconductor dies 70, and the two-dimensional array of third semiconductor dies 70.

In one embodiment, a third one of the first wafer 100, the second wafer 200, and the third wafer 300 may comprise another additional reconstituted wafer in which another additional molding compound matrix 17 laterally surrounds a third two-dimensional array selected from the two-dimensional array of first semiconductor dies, the two-dimensional array of second semiconductor dies, and the two-dimensional array of third semiconductor dies. In one embodiment, the two-dimensional array of third semiconductor dies comprises a two-dimensional periodic array of a repletion unit that includes a combination of a first-type semiconductor die and a second-type semiconductor die that is different from the first-type semiconductor die. In one embodiment, the method may further include the step of dicing a bonded assembly comprising at least the first wafer 100, the second wafer 200, and the third wafer 300 into a plurality of composite packages each comprising an assembly of a respective one of the first semiconductor dies, a respective one of the second semiconductor dies, and a respective one of the third semiconductor dies.

Referring to all drawings and according to various embodiments of the present disclosure, a composite package is provided, which comprises: a vertical stack of a first semiconductor package 10, a second semiconductor package 20, and a third semiconductor package 30, wherein: the first semiconductor package 10 comprises at least one first semiconductor die 70 comprising first metal bonding pads (18, 19); the second semiconductor package 20 comprises at least one second semiconductor die comprising second metal bonding pads (18, 19); the third semiconductor package 30 comprises at least one third semiconductor die comprising third metal bonding pads (18, 19); each vertically neighboring pair of semiconductor packages (10, 20, 30) within the vertical stack is bonded to each other by metal-to-metal bonding between mating pairs of metal bonding pads (18, 19); and vertical sidewalls of at least three semiconductor packages (10, 20, 30) comprising the first semiconductor package 10, the second semiconductor package 20, and the third semiconductor package 30 are vertically coincident with one another.

In one embodiment, a first one of the at least three semiconductor packages (10, 20, 30) comprises a molding compound die frame 17 laterally surrounding one of the at least one first semiconductor die, the at least one second semiconductor die, and the at least one third semiconductor die. In one embodiment, a second one of the at least three semiconductor packages (10, 20, 30) comprises an additional molding compound die frame 17 laterally surrounding another one of the at least one first semiconductor die, the at least one second semiconductor die, and the at least one third semiconductor die. In one embodiment, the at least one first semiconductor die 70 consist of a single semiconductor die having sidewalls that are vertically coincident with outer sidewalls of the molding compound die frame 17. In one embodiment, the at least one third semiconductor die comprises a plurality of third semiconductor dies that are laterally spaced apart from one another by, and are laterally surrounded by, a molding compound die frame.

According to another aspect of the present disclosure, a composite package is provided, which comprises: a vertical stack of a first semiconductor package 10, a second semiconductor package 20, and a third semiconductor package 30, wherein: the first semiconductor package 10 comprises at least one first semiconductor die 70 comprising first metal bonding pads (18, 19); the second semiconductor package 20 comprises at least one second semiconductor die comprising second metal bonding pads (18, 19); the third semiconductor package 30 comprises at least one third semiconductor die comprising third metal bonding pads (18, 19); each vertically neighboring pair of semiconductor packages (10, 20, 30) within the vertical stack is bonded to each other by metal-to-metal bonding between mating pairs of metal bonding pads (18, 19); and each of the at least one second semiconductor die comprises a respective array of through-substrate via (TSV) structures 4 contacting a subset of the second metal bonding pads (18, 19).

In one embodiment, the at least one first semiconductor die 70 comprises first top metal bonding pads (18, 19); the at least one second semiconductor die comprises second bottom metal bonding pads (18, 19) that are bonded to the first top metal bonding pads (18, 19) and further comprises second top metal bonding pads (18, 19); and the at least one third semiconductor die comprises third bottom metal bonding pads (18, 19) that are bonded to the second top metal bonding pads (18, 19). In one embodiment, the subset of the second metal bonding pads (18, 19) comprises the second top metal bonding pads (18, 19). In one embodiment, the subset of the second metal bonding pads (18, 19) comprises the second bottom metal bonding pads (18, 19). In one embodiment, a first one of the at least three semiconductor packages (10, 20, 30) comprises a molding compound die frame 17 laterally surrounding one of the at least one first semiconductor die, the at least one second semiconductor die, and the at least one third semiconductor die. In one embodiment, a second one of the at least three semiconductor packages (10, 20, 30) comprises an additional molding compound die frame 17 laterally surrounding another one of the at least one first semiconductor die, the at least one second semiconductor die, and the at least one third semiconductor die. In one embodiment, sidewalls of the second semiconductor package are vertically coincident with sidewalls of the first semiconductor package and with sidewalls of the third semiconductor package. In one embodiment, the at least one third semiconductor die comprises a plurality of third semiconductor dies. In one embodiment, the at least one second semiconductor die comprises a plurality of second semiconductor dies. In one embodiment, the composite package may further include an array of solder material portions 88 attached to the first semiconductor package.

According to another aspect of the present disclosure, a composite package is provided, which comprises: a vertical stack of a first semiconductor package 10, a second semiconductor package 20, and a third semiconductor package 30, wherein: the first semiconductor package comprises at least one first semiconductor die comprising first metal bonding pads (18, 19); the second semiconductor package comprises at least one second semiconductor die comprising second metal bonding pads (18, 19); the third semiconductor package comprises at least one third semiconductor die comprising third metal bonding pads (18, 19); each vertically neighboring pair of semiconductor packages within the vertical stack is bonded to each other by metal-to-metal bonding between mating pairs of metal bonding pads (18, 19); sidewalls of the second semiconductor package are vertically coincident with sidewalls of the first semiconductor package and with sidewalls of the second semiconductor package; and one or more of the at least one first semiconductor die, the at least one second semiconductor die, and the at least one third semiconductor die comprises a respective sidewall that is laterally offset from the sidewalls of the second semiconductor package.

In one embodiment, a first one of the at least three semiconductor packages (10, 20, 30) comprises a molding compound die frame 17 laterally surrounding one of the at least one first semiconductor die, the at least one second semiconductor die, and the at least one third semiconductor die. In one embodiment, a second one of the at least three semiconductor packages (10, 20, 30) comprises an additional molding compound die frame 17 laterally surrounding another one of the at least one first semiconductor die, the at least one second semiconductor die, and the at least one third semiconductor die. In one embodiment, a horizontal surface of the molding compound die frame 17 is in contact with a horizontal surface of the additional molding compound die frame 17. In one embodiment, the at least one third semiconductor die comprises a plurality of third semiconductor dies.

The various embodiments of the present disclosure may be used to provide a composite package including a vertical stack of three or more semiconductor packages 70 that are vertically bonded to one another through metal-to-metal bonding and optionally through additional dielectric-to-dielectric bonding. The vertical stacking of the semiconductor packages 70 enable fabrication of a high-density high-performance semiconductor package.

The foregoing outlines features of several embodiments so that those skilled in the art may better understand the aspects of the present disclosure. Each embodiment described using the term “comprises” also inherently discloses additional embodiments in which the term “comprises” is replaced with “consists essentially of” or with the term “consists of,” unless expressly disclosed otherwise herein. Whenever two or more elements are listed as alternatives in a same paragraph of in different paragraphs, a Markush group including a listing of the two or more elements is also impliedly disclosed. Whenever the auxiliary verb “may” is used in this disclosure to describe formation of an element or performance of a processing step, an embodiment in which such an element or such a processing step is not performed is also expressly contemplated, provided that the resulting apparatus or device may provide an equivalent result. As such, the auxiliary verb “may” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a semiconductor structure, the method comprising:
providing a first wafer including a two-dimensional array of first semiconductor dies including arrays of first top metal bonding pads and arrays of first bottom metal bonding pads;
providing a second wafer including a two-dimensional array of second semiconductor dies including arrays of second top metal bonding pads and arrays of second bottom metal bonding pads;
bonding the second wafer to the first wafer by performing a first metal-to-metal bonding process in which the arrays of first top metal bonding pads are bonded to the arrays of second bottom metal bonding pads through first intermetallic diffusion;
providing a third wafer including a two-dimensional array of third semiconductor dies including arrays of third bottom metal bonding pads; and
bonding the third wafer to the second wafer by performing a second metal-to-metal bonding process in which the arrays of second top metal bonding pads are bonded to the arrays of third bottom metal bonding pads through second intermetallic diffusion.

2. The method of claim 1, wherein the third wafer comprises a reconstituted wafer in which third semiconductor dies of the array of third semiconductor dies are laterally surrounded by a molding compound matrix.

3. The method of claim 2, wherein the second wafer comprises an additional reconstituted wafer in which second semiconductor dies of the array of second semiconductor dies are laterally surrounded by an additional molding compound matrix.

4. The method of claim 3, wherein the first semiconductor dies are interconnected to one another, and each of the first semiconductor dies comprises a respective portion of a semiconductor substrate that continuously extends over an entire area of the first wafer.

5. The method of claim 3, wherein the first wafer comprises another additional reconstituted wafer in which the first semiconductor dies are laterally surrounded by another additional molding compound matrix.

6. The method of claim 1, wherein:
the third semiconductor dies comprises first-type semiconductor dies and second-type semiconductor dies; and
the two-dimensional array of third semiconductor dies comprises a two-dimensional periodic array of a repletion unit that includes a combination of a first-type semiconductor die and a second-type semiconductor die that is different from the first-type semiconductor die.

7. The method of claim 1, further comprising dicing a bonded assembly comprising at least the first wafer, the second wafer, and the third wafer into a plurality of composite packages each comprising an assembly of a respective one of the first semiconductor dies, a respective one of the second semiconductor dies, and a respective one of the third semiconductor dies.

8. The method of claim 7, wherein each of the composite packages comprises a respective additional one of the third semiconductor dies.

9. A method of forming a semiconductor structure, the method comprising:
attaching a first wafer including a two-dimensional array of first semiconductor dies including arrays of first top metal bonding pads and arrays of first bottom metal bonding pads to a top surface of a first carrier wafer;
attaching a second wafer including a two-dimensional array of second semiconductor dies including arrays of second top metal bonding pads and arrays of second bottom metal bonding pads to the first wafer by performing a first metal-to-metal bonding process in which the arrays of first top metal bonding pads are bonded to the arrays of second bottom metal bonding pads through first intermetallic diffusion; and
attaching a third wafer including a two-dimensional array of third semiconductor dies including arrays of third bottom metal bonding pads to the second wafer by performing a second metal-to-metal bonding process in which the arrays of second top metal bonding pads are bonded to the arrays of third bottom metal bonding pads through second intermetallic diffusion.

10. The method of claim 9, further comprising:
attaching a second carrier wafer to a top surface of a bonded assembly comprising the first carrier wafer, the first wafer, the second wafer, and the third wafer; and
detaching the first carrier wafer from the first wafer after attaching the second carrier wafer to the bonded assembly.

11. The method of claim 10, further comprising:
attaching arrays of solder material portions to the arrays of first bottom metal bonding pads; and
dicing the bonded assembly into a plurality of composite packages each comprising a vertical stack of a respective one of the first semiconductor dies, a respective one of a second semiconductor dies, and a respective one of the third semiconductor dies.

12. The method of claim 9, wherein one of the first wafer, the second wafer, and the third wafer comprises a reconstituted wafer in which a molding compound matrix laterally surrounds the first semiconductor dies, the second semiconductor dies, or the third semiconductor dies.

13. The method of claim 12, wherein another of the first wafer, the second wafer, and the third wafer comprises an additional reconstituted wafer comprising an additional molding compound matrix.

14. The method of claim 9, wherein:
the third semiconductor dies comprises first-type semiconductor dies and second-type semiconductor dies; and
the third wafer comprises a two-dimensional periodic array of a repletion unit that includes a combination of a first-type semiconductor die and a second-type semiconductor die that is different from the first-type semiconductor die.

15. The method of claim 9, wherein:
the two-dimensional array of third semiconductor dies including arrays of third top metal bonding pads; and
the method comprises attaching a fourth wafer comprising a two-dimensional array of fourth semiconductor dies including arrays of fourth bottom metal bonding pads to the third wafer by performing a third metal-to-metal bonding process in which the arrays of third top metal bonding pads are bonded to the arrays of fourth bottom metal bonding pads through third intermetallic diffusion.

16. A composite package comprising:
a vertical stack of a first semiconductor package, a second semiconductor package, and a third semiconductor package, wherein:
the first semiconductor package comprises at least one first semiconductor die comprising first metal bonding pads;
the second semiconductor package comprises at least one second semiconductor die comprising second metal bonding pads;
the third semiconductor package comprises at least one third semiconductor die comprising third metal bonding pads;
each vertically neighboring pair of semiconductor packages within the vertical stack is bonded to each other by metal-to-metal bonding between mating pairs of metal bonding pads; and
vertical sidewalls of at least three semiconductor packages comprising the first semiconductor package, the second semiconductor package, and the third semiconductor package are vertically coincident to one another.

17. The composite package of claim 16, wherein a first one of the at least three semiconductor packages comprises a molding compound die frame laterally surrounding one of the at least one first semiconductor die, the at least one second semiconductor die, and the at least one third semiconductor die.

18. The composite package of claim 17, wherein a second one of the at least three semiconductor packages comprises an additional molding compound die frame laterally surrounding another one of the at least one first semiconductor die, the at least one second semiconductor die, and the at least one third semiconductor die.

19. The composite package of claim 17, wherein the at least one first semiconductor die consist of a single semiconductor die having sidewalls that are vertically coincident with outer sidewalls of the molding compound die frame.

20. The composite package of claim 16, wherein the at least one third semiconductor die comprises a plurality of third semiconductor dies that are laterally spaced apart from one another by, and are laterally surrounded by, a molding compound die frame.
